(19) United States
(12) Patent Application Publication
(10) Pub. No.: US 2026/0045913 A1
(43) Pub. Date: Feb. 12, 2026

(54) RADIO FREQUENCY CIRCUIT, TRACKER MODULE AND AMPLIFICATION METHOD

(71) Applicant: Murata Manufacturing Co., Ltd., Nagaokakyo-shi (JP)

(72) Inventors: Sho OKAMOTO, Nagaokakyo-shi (JP); Muneharu KATO, Nagaokakyo-shi (JP); Kouji YAMAGUCHI, Nagaokakyo-shi (JP)

(21) Appl. No.: 19/365,931

(22) Filed: Oct. 22, 2025

Related U.S. Application Data
(63) Continuation of application No. PCT/JP2024/006939, filed on Feb. 27, 2024.

(30) Foreign Application Priority Data
Apr. 26, 2023 (JP) 2023-072529

(51) Int. Cl. H03F 1/02; H03F 3/21

(52) U.S. Cl. CPC H03F 1/0211; H03F 3/211; H03F 2200/102; H03F 2200/451

(57) ABSTRACT

A radio frequency circuit is provided that includes power amplifiers that amplify first and second radio frequency signals, respectively; and a tracker circuit that supplies a voltage to the power amplifiers. The tracker circuit includes a pre-regulator circuit that converts an input voltage into a regulated voltage; switched-capacitor circuits that generate a first plurality and a second plurality of discrete voltages, respectively, based on the regulated voltage; a first supply modulator that selectively outputs at least one voltage of the first plurality of discrete voltages to a power amplifier; and a second supply modulator that selectively outputs at least one voltage of the second plurality of discrete voltages to a power amplifier. The first radio frequency signal is different than the second radio frequency signal.

### CROSS REFERENCE TO RELATED APPLICATIONS

This application is a continuation of International Application No. PCT/JP2024/006939, filed Feb. 27, 2024, which claims priority to Japanese Patent Application No. 2023-072529, filed Apr. 26, 2023, the contents of each of which are hereby incorporated by reference in their entireties.

### TECHNICAL FIELD

The present disclosure relates to a radio frequency circuit, a tracker module, and an amplification method.

### BACKGROUND

In general, Japanese Unexamined Patent Application Publication No. 2019-140671 discloses a circuit that amplifies a WLAN (Wireless Local Area Network) signal. Further, U.S. Pat. No. 8,829,993 discloses a D-ET (Digital Envelope Tracking) technology for improving power efficiency of a power amplifier.

However, in cellular networks and WLANs, the modulation band width (i.e., channel bandwidth) of radio frequency signals and the bit rate of digital modulation systems tend to increase, and the adoption of a D-ET mode is desired. However, since the maximum output power, the modulation band width, and/or the required quality (for example, the allowable value of EVM (Error Vector Magnitude)) are different between the Sub6 signal of a cellular network and a WLAN signal or the millimeter-wave signal of the cellular network, the power efficiency of a power amplifier and/or a tracker circuit may deteriorate.

### SUMMARY OF THE INVENTION

Therefore, the exemplary aspects of the present disclosure provide a radio frequency circuit, a tracker module, and an amplification method with improved power efficiency.

In an exemplary aspect, a radio frequency circuit is provided that includes a first power amplifier configured to amplify a first radio frequency signal; a second power amplifier configured to amplify a second radio frequency signal; and a tracker circuit configured to supply a voltage to the first power amplifier and the second power amplifier. The tracker circuit includes a converter circuit configured to convert an input voltage into a regulated voltage; a first switched-capacitor circuit configured to generate a first plurality of discrete voltages based on the regulated voltage; a second switched-capacitor circuit configured to generate a second plurality of discrete voltages based on the regulated voltage; a first supply modulator configured to selectively output at least one voltage of the first plurality of discrete voltages to the first power amplifier based on the first radio frequency signal; and a second supply modulator configured to selectively output at least one voltage of the second plurality of discrete voltages to the second power amplifier based on the second radio frequency signal. In an exemplary aspect, the first radio frequency signal is a Sub6 signal of a cellular network, and the second radio frequency signal is a wireless local area network signal or a millimeter-wave signal of the cellular network.

In another exemplary aspect, a tracker module is provided that includes a module laminate; at least one integrated circuit disposed on the module laminate; a first external connection terminal externally connected to a first power amplifier configured to amplify a first radio frequency signal; and a second external connection terminal externally connected to a second power amplifier configured to amplify a second radio frequency signal. The at least one integrated circuit includes a plurality of switches included in a first switched-capacitor circuit, a second switched-capacitor circuit, a first supply modulator, and a second supply modulator, the first switched-capacitor circuit is configured to generate a first plurality of discrete voltages based on a regulated voltage, the second switched-capacitor circuit is configured to generate a second plurality of discrete voltages based on the regulated voltage, the first supply modulator is configured to selectively output at least one voltage of the first plurality of discrete voltages to the first external connection terminal based on the first radio frequency signal, the second supply modulator is configured to selectively output at least one voltage of the second plurality of discrete voltages to the second external connection terminal based on the second radio frequency signal. In an exemplary aspect, the first radio frequency signal is a Sub6 signal of a cellular network, and the second radio frequency signal is a wireless local area network signal or a millimeter-wave signal of the cellular network.

In another exemplary aspect, an amplification method is provided that includes converting an input voltage into a regulated voltage; generating a first plurality of discrete voltages based on the regulated voltage; selectively supplying at least one voltage of the first plurality of discrete voltages to a first power amplifier based on an envelope signal of a first radio frequency signal; amplifying the first radio frequency signal with the first power amplifier; generating a second plurality of discrete voltages based on the regulated voltage; selectively supplying at least one voltage of the second plurality of discrete voltages to a second power amplifier based on an envelope signal of a second radio frequency signal; and amplifying the second radio frequency signal with the second power amplifier. In an exemplary aspect, the first radio frequency signal is a Sub6 signal of a cellular network, and the second radio frequency signal is a wireless local area network signal or a millimeter-wave signal of the cellular network.

According to the exemplary aspects of the present disclosure, the power efficiency is improved.

### BRIEF DESCRIPTION OF DRAWINGS

FIG. 1A is a graph showing an example of the transition of a power supply voltage in an APT (Average Power Tracking) mode.

FIG. 1B is a graph showing an example of the transition of a power supply voltage in an A-ET (Analog Envelope Tracking) mode.

FIG. 1C is a graph showing an example of the transition of a power supply voltage in a D-ET mode.

FIG. 2 is a circuit configuration diagram of a communication device according to a first exemplary embodiment.

FIG. 3 is a circuit configuration diagram of a pre-regulator circuit according to the first exemplary embodiment.

FIG. 4 is a circuit configuration diagram of a first switched-capacitor circuit and two first supply modulators according to the first exemplary embodiment.

FIG. 5 is a circuit configuration diagram of a second switched-capacitor circuit, a second supply modulator, and a digital control circuit according to the first exemplary embodiment.

FIG. 6 is a flowchart showing an amplification method according to the first exemplary embodiment.

FIG. 7 is a plan view of a tracker module according to the first exemplary embodiment.

FIG. 8 is a bottom view of the tracker module according to the first exemplary embodiment.

FIG. 9 is a circuit configuration diagram of a communication device according to a second exemplary embodiment.

FIG. 10 is a circuit configuration diagram of a second switched-capacitor circuit and a second supply modulator according to the second exemplary embodiment.

FIG. 11 is a circuit configuration diagram of a communication device according to a third exemplary embodiment.

FIG. 12 is a circuit configuration diagram of a second switched-capacitor circuit and a second supply modulator according to the third exemplary embodiment.

### DETAILED DESCRIPTION OF EMBODIMENTS

Exemplary embodiments of the present disclosure will be described in detail below with reference to the drawings. It is noted that all the embodiments described below are comprehensive or specific examples. The numerical values, shapes, materials, components, arrangement of components, connection forms and the like shown in the following embodiments are examples and are not intended to limit the present disclosure.

It is be noted that each drawing is schematic with emphasis, omissions, or proportions adjusted as appropriate to illustrate the exemplary aspects of the present disclosure, is not necessarily strictly illustrative, and may differ from actual shapes, positional relationships, and proportions. In each drawing, substantially identical components are denoted by the same reference signs, and duplicate descriptions may be omitted or simplified.

In the following drawings, the x-axis and the y-axis are axes orthogonal to each other on a plane parallel to a main surface of a module laminate. Specifically, when the module laminate has a rectangular shape in plan view, the x-axis is parallel to a first side of the module laminate, and the y-axis is parallel to a second side orthogonal to the first side of the module laminate. Further, the z-axis is an axis perpendicular to the main surface of the module laminate, and the positive direction of the z-axis indicates an upward direction and the negative direction of the z-axis indicates a downward direction.

In the following description, the term “connected” includes not only being directly connected by connection terminals and/or wiring conductors, but also being electrically connected via other circuit elements. Moreover, the term “directly connected” indicates directly connected by connection terminals and/or wiring conductors without other circuit elements interposed therebetween. The expression “C is connected between A and B” indicates that one end of C is connected to A and the other end of C is connected to B, and that C is connected in series to a path connecting A and B. The term “a path connecting A and B” refers to a path composed of a conductor that electrically connects A to B.

According to an exemplary aspect, the term “terminal” refers to a point at which a conductor in an element terminates. It is also noted that when the impedance of a conductor between elements is sufficiently low, the terminal is also interpreted as any point on the conductor between elements or as the entire conductor, instead of being interpreted only as a single point.

The expression “a component is disposed on a substrate” includes a state in which the component is disposed on a main surface of the substrate and a state in which the component is disposed inside the substrate. The expression “a component is disposed on a main surface of a substrate” includes a state in which the component is disposed above the main surface without contacting the main surface (for example, a component is stacked on another component disposed in contact with the main surface) in addition to a state in which the component is disposed in contact with the main surface of the substrate. The expression “a component is disposed on a main surface of a substrate” may also include a state in which the component is disposed in a recessed portion formed in the main surface. The expression “a component is disposed in a substrate” includes a state in which the entire component is disposed between both main surfaces of the substrate but a portion of the component is not covered by the substrate and a state in which only a portion of the component is disposed in the substrate, in addition to a state in which the component is encapsulated in the module laminate.

For purposes of this disclosure, the expression “B is closer to A than C” indicates that the distance between A and B is shorter than the distance between A and C. Here, the term “the distance between A and B” refers to the shortest distance between A and B. In other words, the term “the distance between A and B” refers to the length of the shortest line segment among a plurality of line segments connecting any point on the surface of A and any point on the surface of B.

According to exemplary aspects, the terms indicating relationships between elements, such as “parallel” and “orthogonal”, and the terms indicating the shape of elements, such as “rectangular”, as well as numerical ranges do not represent only strict meanings, but also include substantially equivalent ranges, for example, with errors of several percent.

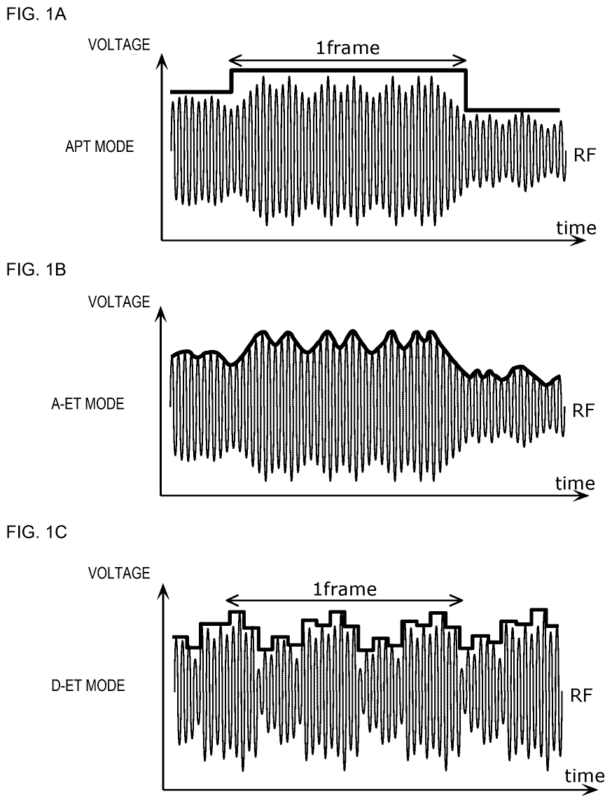

Here, the term “tracking mode”, which is a technology for amplifying a radio frequency signal with high efficiency, will be described first before describing the embodiments. In a tracking mode, a power supply voltage dynamically regulated over time based on a radio frequency signal is supplied to a power amplifier. There are several types of tracking modes; here, an APT mode, an A-ET mode, and a D-ET mode will be described with reference to FIGS. 1A to 1C. In FIGS. 1A to 1C, the horizontal axis represents time, and the vertical axis represents voltage. The thick solid line represents a power supply voltage, and the thin solid line (waveform) represents a modulated signal.

FIG. 1A is a graph showing an example of the transition of a power supply voltage in an APT mode. The APT mode is a mode in which the power supply voltage is changed to a plurality of discrete voltage levels in units of one frame based on the average power.

According to an exemplary aspect, a frame is a unit that forms a radio frequency signal (e.g., a modulated signal). For example, in 5GNR (5th Generation New Radio) and LTE (Long Term Evolution), a frame includes 10 sub-frames, each sub-frame includes a plurality of slots, and each slot is composed of a plurality of symbols. The sub-frame length is 1 millisecond (ms), and the frame length is 10 ms.

A mode in which the voltage level is changed in units of one frame or larger units based on the average power is referred to as an APT mode. The APT mode is distinguished from a mode in which the voltage level is changed in units of smaller than one frame (for example, a unit of sub-frame, slot or symbol).

FIG. 1B is a graph showing an example of the transition of a power supply voltage in an A-ET mode. The A-ET mode is a mode in which the power supply voltage is continuously changed based on an envelope signal. In the A-ET mode, the power supply voltage can track the envelope of the modulated signal.

The envelope signal is a signal that indicates the envelope of the modulated signal. The envelope value is expressed, for example, by the square root of (I²+Q²). Here, (I, Q) represents a constellation point. The constellation point is a point that represents a digitally modulated signal on a constellation diagram. (I, Q) are determined by a BBIC (Baseband Integrated Circuit) based on transmission information, for example.

FIG. 1C is a graph showing an example of the transition of a power supply voltage in a D-ET mode. The D-ET mode is a mode in which the power supply voltage is changed to a plurality of discrete voltage levels in one frame based on an envelope signal. In the D-ET mode, the power supply voltage can track the envelope of the modulated signal. In the D-ET mode, the power supply voltage changes at a shorter time interval than in the APT mode.

### First Exemplary Embodiment

A first exemplar embodiment will be described below. A communication device 7 according to the present embodiment can be used to provide a wireless connection. For example, the communication device 7 can be mounted on UE (User Equipment) in a cellular network (also referred to as a mobile network), in which examples of the UE include a mobile phone, a smartphone, a tablet computer, and a wearable device. In another example, the communication device 7 can be mounted on to provide a wireless connection to an IoT (Internet of Things) sensor/device, a medical/healthcare device, a car, a UAV (Unmanned Aerial Vehicle) (i.e., a so-called drone), or an AGV (Automated Guided Vehicle). In yet another example, the communication device 7 can be mounted to provide a wireless connection at a wireless access point or a wireless hot spot.

### [1.1 Circuit Configuration of Communication Device 7]

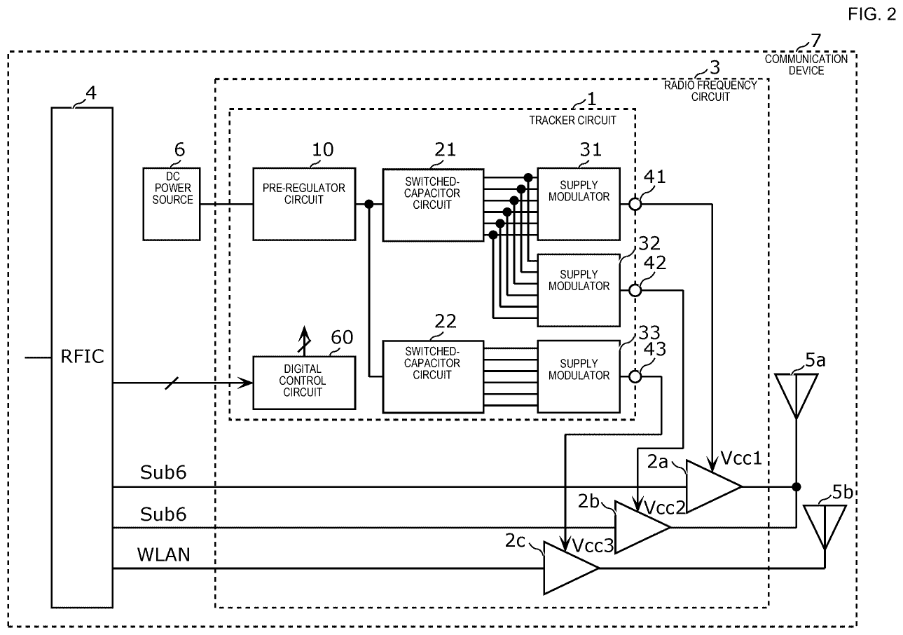

The circuit configuration of the communication device 7 according to the present embodiment will be described with reference to FIG. 2. FIG. 2 is a circuit configuration diagram of the communication device 7 according to the present embodiment.

It is noted that FIG. 2 is an exemplary circuit configuration, and the communication device 7 may be mounted using any of a wide variety of circuit mounting and circuit techniques. Therefore, the description of the communication device 7 provided below is not to be interpreted in a limited manner.

The communication device 7 according to the present embodiment includes a radio frequency circuit 3, an RFIC (Radio Frequency Integrated Circuit) 4, antennas 5a and 5b, and a DC power source 6, in which the radio frequency circuit 3 includes a tracker circuit 1 and power amplifiers 2a to 2c. It is noted that the radio frequency circuit 3 may omit the power amplifier 2b in an exemplary aspect.

The tracker circuit 1 is connected between the DC power source 6 and the power amplifiers 2a to 2c and can supply power supply voltages (Vcc1 to Vcc3) to the power amplifiers 2a to 2c. The circuit configuration of the tracker circuit 1 will be described later.

The power amplifier 2a is an example of a first power amplifier and can amplify the Sub6 signal of a cellular network. The power amplifier 2b can also amplify the Sub6 signal of the cellular network. The power amplifiers 2a and 2b are connected between the RFIC 4 and the antenna 5a and are further connected to the tracker circuit 1. Note that the power amplifier 2a and/or the power amplifier 2b may amplify a radio frequency signal other than the Sub6 signal and may amplify, for example, a signal in a frequency band of a 7 GHz band.

The power amplifier 2c is an example of a second power amplifier and can amplify a WLAN signal. The power amplifier 2c is connected between the RFIC 4 and the antenna 5b and is further connected to the tracker circuit 1. Note that the power amplifier 2c may amplify a radio frequency signal other than the WLAN signal.

The Sub6 signal of the cellular network is an example of a first radio frequency signal and is a signal of a frequency band of a 6 GHz or lower used in the cellular network. For purposes of this disclosure, a cellular network refers to a telecommunications network constructed using mobile communication (For example, 5G NR (5th Generation New Radio), 4G LTE (4th Generation Long Term Evolution), 2G GSM (2nd Generation Global System of Mobile communications), or the like).

The WLAN signal is an example of a second radio frequency signal and is a signal of a 2.4 GHz, 5 GHZ, 6 GHz or 7 GHz band used in WLANs. Moreover, a WLAN refers to a local area network constructed using wireless communication (for example, IEEE802.11).

The RFIC 4 is an example of a signal processing circuit and can supply the Sub6 signal of the cellular network and the WLAN signal to the power amplifiers 2a to 2c. Specifically, the RFIC 4 can receive a digital IQ signal from, for example, a BBIC (not shown) and generate a Sub6 signal and a WLAN signal by performing digital-to-analog conversion, quadrature modulation, up-conversion or the like on the digital IQ signal. Further, the RFIC 4 may include a control unit for controlling the radio frequency circuit 3. It is noted that some or all of the functions of the control unit of the RFIC 4 may be mounted outside the RFIC 4 (for example, in the radio frequency circuit 3 or the like). Further, the RFIC 4 may be divided into an RFIC for the Sub6 signal of the cellular network and an RFIC for the WLAN signal.

The antenna 5a can transmit the Sub6 signal amplified by the power amplifier 2a or 2b to the outside. The antenna 5b can transmit the WLAN signal amplified by the power amplifier 2c to the outside. It is noted that the antenna 5a and/or the antenna 5b may be omitted from the communication device 7 according to various exemplary aspects. Also, the communication device 7 may further include one or more antennas in addition to the antennas 5a and 5b.

The DC power source 6 can supply a DC voltage to the tracker circuit 1. For example, a rechargeable battery can be used as the DC power source 6, but the DC power source 6 is not limited to a rechargeable battery. Moreover, the DC power source 6 may be omitted from the communication device 7 in an exemplary aspect.

It is noted that the circuit configurations of the communication device 7 and the radio frequency circuit 3 shown in FIG. 2 are examples and are not limited to such examples. For example, the communication device 7 may include a baseband signal processing circuit that performs signal processing using a frequency band lower than the radio frequency signal. Further, the radio frequency circuit 3 may include a filter connected between the power amplifier 2a and the antenna 5a, and/or a filter connected between the power amplifier 2b and the antenna 5a. Further, the radio frequency circuit 3 may include a filter connected between the power amplifier 2c and the antenna 5b. Further, the radio frequency circuit 3 may include a switch connected between the power amplifiers 2a to 2c, and the antennas 5a and 5b.

### [1.2 Circuit Configuration of Tracker Circuit 1]

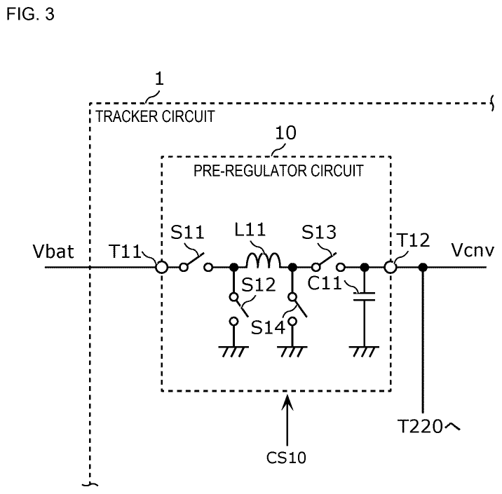

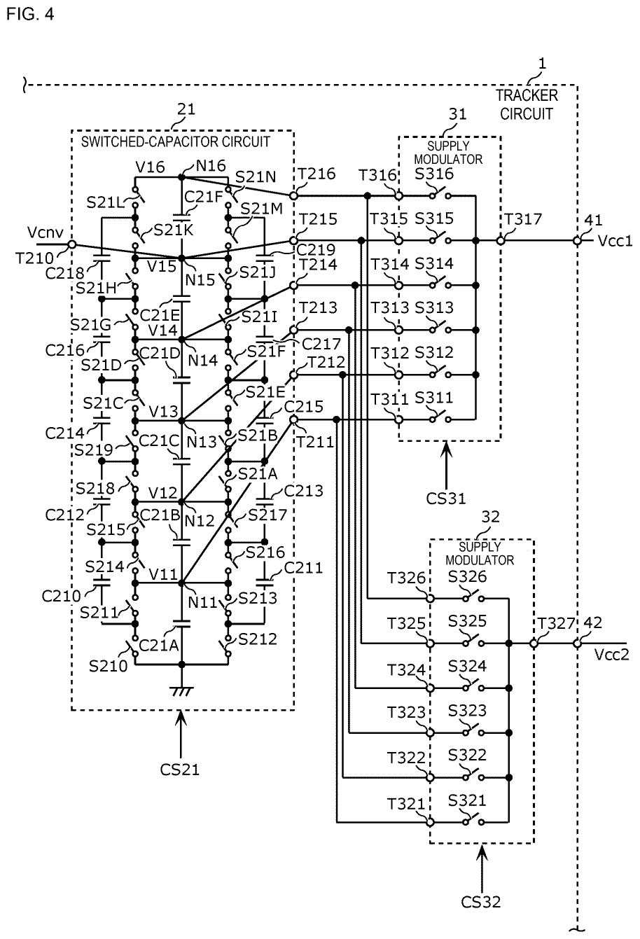

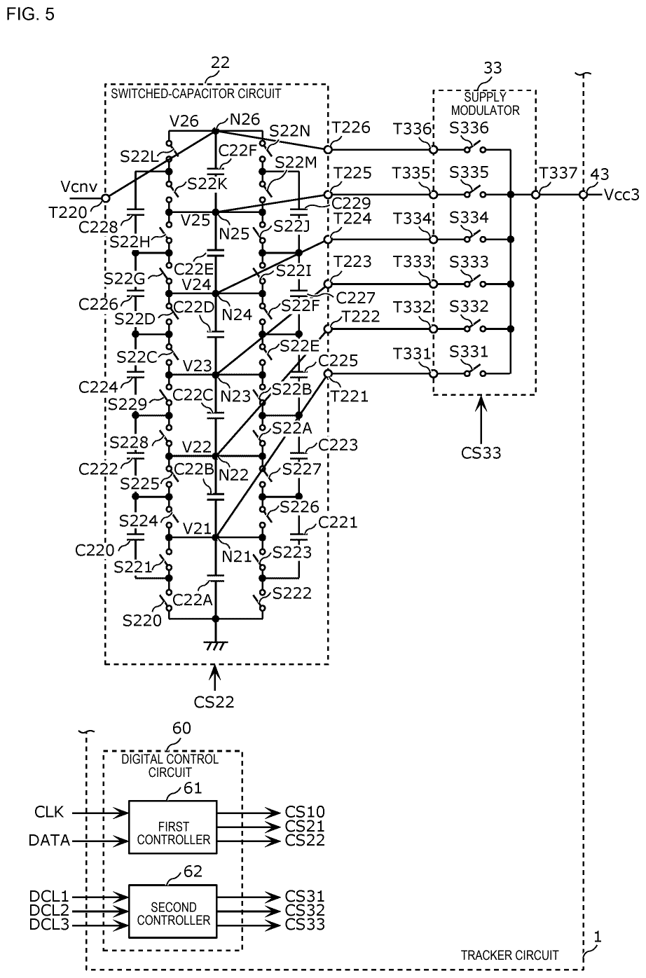

Next, the circuit configuration of the tracker circuit 1 will be described with reference to FIGS. 2 to 5. FIG. 3 is a circuit configuration diagram of a pre-regulator circuit 10 according to the present embodiment. FIG. 4 is a circuit configuration diagram of a switched-capacitor circuit 21 and supply modulators 31 and 32 according to the present embodiment. FIG. 5 is a circuit configuration diagram of a switched-capacitor circuit 22, a supply modulator 33 and a digital control circuit 60 according to the present embodiment.

It is noted that FIGS. 2 to 5 are exemplary circuit configurations, and the tracker circuit 1, the pre-regulator circuit 10, the switched-capacitor circuits 21 and 22, the supply modulators 31 to 33, and the digital control circuit 60 may be mounted using any of a wide variety of circuit mounting and circuit techniques. Therefore, the description of each circuit provided below is not to be interpreted in a limited manner.

The tracker circuit 1 includes the pre-regulator circuit 10, the switched-capacitor circuits 21 and 22, the supply modulators 31 to 33, external connection terminals 41 to 43, and the digital control circuit 60. It is noted that the tracker circuit 1 may omit the pre-regulator circuit 10 and/or the supply modulator 32 and the external connection terminal 42 according to various exemplary aspects.

The pre-regulator circuit 10 is an example of a converter circuit and is sometimes referred to as a magnetic regulator or a DC (Direct Current)/DC converter. In the present embodiment, the pre-regulator circuit 10 is a buck-boost converter having one input and one output and can convert a DC voltage (Vbat) from the DC power source 6 into an output voltage (regulated voltage). Note that the pre-regulator circuit 10 may alternatively be a buck converter or a boost converter. The pre-regulator circuit 10 can change the output voltage based on, for example, a digital control signal from the RFIC 4. The circuit configuration of the pre-regulator circuit 10 will be described later with reference to FIG. 3.

The switched-capacitor circuit 21 is an example of a first switched-capacitor circuit that is configured to generate a first plurality of discrete voltages based on the regulated voltage supplied from the pre-regulator circuit 10. In the present embodiment, the switched-capacitor circuit 21 is configured to generate the first plurality of discrete voltages by raising and lowering the regulated voltage. The circuit configuration of the switched-capacitor circuit 21 will be described later with reference to FIG. 4.

The switched-capacitor circuit 22 is an example of a second switched-capacitor circuit and is configured to generate a second plurality of discrete voltages based on the regulated voltage supplied from the pre-regulator circuit 10. In the present embodiment, the switched-capacitor circuit 22 is configured to generate the second plurality of discrete voltages by lowering the regulated voltage without raising the regulated voltage. The circuit configuration of the switched-capacitor circuit 22 will be described later with reference to FIG. 5.

The first plurality of discrete voltages includes voltages at levels different from any of the second plurality of discrete voltages. The second plurality of discrete voltages includes voltages at levels different from any of the first plurality of discrete voltages. In other words, the first plurality of discrete voltages is not a subset of the second plurality of discrete voltages, and the second plurality of discrete voltages is not a subset of the first plurality of discrete voltages.

The supply modulator 31 is an example of a first supply modulator and can selectively output at least one of the first plurality of discrete voltages generated by the switched-capacitor circuit 21 to the power amplifier 2a. In other words, the supply modulator 31 can select at least one voltage from the first plurality of discrete voltages and supply the selected voltage to the power amplifier 2a. The circuit configuration of the supply modulator 31 will be described later with reference to FIG. 4.

The supply modulator 32 can selectively output at least one of the first plurality of discrete voltages generated by the switched-capacitor circuit 21 to the power amplifier 2b. In other words, the supply modulator 32 can select at least one voltage from the first plurality of discrete voltages and supply the selected voltage to the power amplifier 2b. The circuit configuration of the supply modulator 32 will be described later with reference to FIG. 4.

The supply modulator 33 is an example of a second supply modulator and can selectively output at least one of the second plurality of discrete voltages generated by the switched-capacitor circuit 22 to the power amplifier 2c. In other words, the supply modulator 33 can select at least one voltage from the second plurality of discrete voltages and supply the selected voltage to the power amplifier 2c. The circuit configuration of the supply modulator 33 will be described later with reference to FIG. 4.

The external connection terminal 41 is an example of a first external connection terminal and is an output terminal for supplying a power supply voltage (Vcc1) to the power amplifier 2a. The external connection terminal 41 is externally connected to the power amplifier 2a and internally connected to the supply modulator 31.

The external connection terminal 42 is an output terminal for supplying a power supply voltage (Vcc2) to the power amplifier 2b. The external connection terminal 42 is externally connected to the power amplifier 2b and internally connected to the supply modulator 32.

The external connection terminal 43 is an example of a second external connection terminal and is an output terminal for supplying a power supply voltage (Vcc3) to the power amplifier 2c. The external connection terminal 43 is externally connected to the power amplifier 2c and internally connected to the supply modulator 33.

The digital control circuit 60 can control the pre-regulator circuit 10, the switched-capacitor circuits 21 and 22, and the supply modulators 31 to 33, based on a digital control signal from the RFIC 4. It is noted that the digital control circuit 60 may be omitted from the tracker circuit 1 in an exemplary aspect. The digital control circuit 60 will be described later with reference to FIG. 5.

It is noted that the circuit configuration of the tracker circuit 1 is an example and is not limited to such an example. For example, the tracker circuit 1 may include a PSN (Pulse Shaping Network) connected between the supply modulator 31 and the external connection terminal 41 and/or a PSN connected between the supply modulator 32 and the external connection terminal 42. Also, the tracker circuit 1 may include a PSN connected between the supply modulator 33 and the external connection terminal 43.

### [1.2.1 Circuit Configuration of Pre-Regulator Circuit 10]

Next, the circuit configuration of the pre-regulator circuit 10 included in the tracker circuit 1 will be described with reference to FIG. 3.

The pre-regulator circuit 10 includes an input terminal T11, an output terminal T12, switches S11 to S14, a power inductor L11, and a capacitor C11.

The input terminal T11 is a terminal for receiving the DC voltage (Vbat) as an input voltage from the DC power source 6. The input terminal T11 is externally connected to the DC power source 6 and internally connected to the switch S11.

The output terminal T12 is a terminal for supplying the regulated voltage to the switched-capacitor circuits 21 and 22. The output terminal T12 is externally connected to input terminals T210 and T220 of the switched-capacitor circuits 21 and 22 and internally connected to the switch S13.

The power inductor L11 is an inductor used for raising and lowering the DC voltage (Vbat). One end of the power inductor L11 is connected to the switches S11 and S12, and the other end of the power inductor L11 is connected to the switches S13 and S14.

The switch S11 is connected between the input terminal T11 and one end of the power inductor L11. In such a connection configuration, the switch S11 can switch the connection and disconnection between the input terminal T11 and one end of the power inductor L11 by being switched ON and OFF.

The switch S12 is connected between one end of the power inductor L11 and the ground. In such a connection configuration, the switch S12 can switch the connection and disconnection between one end of the power inductor L11 and the ground by being switched ON and OFF.

The switch S13 is connected between the other end of the power inductor L11 and the output terminal T12. In such a connection configuration, the switch S13 can switch the connection and disconnection between the other end of the power inductor L11 and the output terminal T12 by being switched ON and OFF.

The switch S14 is connected between the other end of the power inductor L11 and the ground. In such a connection configuration, the switch S14 can switch the connection and disconnection between the other end of the power inductor L11 and the ground by being switched ON and OFF.

The capacitor C11 is connected between a path between the switch S13 and the output terminal T12 and the ground. Specifically, one of the two electrodes of the capacitor C11 is connected to the switch S13 and the output terminal T12, and the other of the two electrodes of the capacitor C11 is connected to the ground.

It is noted that the configuration of the pre-regulator circuit 10 shown in FIG. 3 is an example and is not limited to such an example. For example, some of the switches S11 to S14 may be replaced with diode(s). Also, some or all of the pre-regulator circuit 10 may be omitted from the tracker circuit 1 in various exemplary aspects.

### [1.2.2 Circuit Configuration of Switched-Capacitor Circuit 21]

Next, the circuit configuration of the switched-capacitor circuit 21 included in the tracker circuit 1 will be described with reference to FIG. 4.

The switched-capacitor circuit 21 has a ladder type circuit configuration and is configured to generate a first plurality of discrete voltages (V11 to V16). Specifically, the switched-capacitor circuit 21 includes capacitors C210 to C21F, switches S210 to S21N, the input terminal T210, and output terminals T211 to T216. Energy and electric charges are inputted from the pre-regulator circuit 10 to a node N15 via the input terminal T210 and are extracted from nodes N11 to N16 to the supply modulators 31 and 32 via the output terminals T211 to T216.

The input terminal T210 is a terminal for receiving the regulated voltage from the pre-regulator circuit 10. The input terminal T210 is externally connected to the pre-regulator circuit 10 and internally connected to the node N15.

The output terminal T211 is a terminal for supplying a voltage (V11) of the first plurality of discrete voltages (V11 to V16) to the supply modulators 31 and 32. The output terminal T211 is externally connected to the supply modulators 31 and 32 and internally connected to the node N11.

The output terminal T212 is a terminal for supplying a voltage (V12) of the first plurality of discrete voltages (V11 to V16) to the supply modulators 31 and 32. The output terminal T212 is externally connected to the supply modulators 31 and 32 and internally connected to the node N12.

The output terminal T213 is a terminal for supplying a voltage (V13) of the first plurality of discrete voltages (V11 to V16) to the supply modulators 31 and 32. The output terminal T213 is externally connected to the supply modulators 31 and 32 and internally connected to the node N13.

The output terminal T214 is a terminal for supplying a voltage (V14) of the first plurality of discrete voltages (V11 to V16) to the supply modulators 31 and 32. The output terminal T214 is externally connected to the supply modulators 31 and 32 and internally connected to the node N14.

The output terminal T215 is a terminal for supplying a voltage (V15) of the first plurality of discrete voltages (V11 to V16) to the supply modulators 31 and 32. The output terminal T215 is externally connected to the supply modulators 31 and 32 and internally connected to the node N15. The output terminal T215 may be integrated with the input terminal T210.

The output terminal T216 is a terminal for supplying a voltage (V16) of the first plurality of discrete voltages (V11 to V16) to the supply modulators 31 and 32. The output terminal T216 is externally connected to the supply modulators 31 and 32 and internally connected to the node N16.

The capacitors C210 to C219 can be flying capacitors (sometimes referred to as transfer capacitors) and can be configured to raise and/or lower the regulated voltage (V15) supplied from the pre-regulator circuit 10. Specifically, the capacitors C210 to C219 transfer electric charges between the capacitors C210 to C219 and the nodes N11 to N16 and the ground so that V11 to V16 satisfying (V16−V15):(V15−V14):(V14−V13):(V13−V12):(V12−V11):(V11−VG)=1:1:1:1:1:1 and V16>V15>V14>V13>V12>V11>VG are maintained at the six nodes N11 to N16. VG represents the ground potential.

One of the two electrodes of the capacitor C210 is connected to one end of the switch S210 and one end of the switch S211. The other of the two electrodes of the capacitor C210 is connected to one end of the switch S214 and one end of the switch S215.

One of the two electrodes of the capacitor C211 is connected to one end of the switch S212 and one end of the switch S213. The other of the two electrodes of the capacitor C211 is connected to one end of the switch S216 and one end of the switch S217.

One of the two electrodes of the capacitor C212 is connected to one end of the switch S214 and one end of the switch S215. The other of the two electrodes of the capacitor C212 is connected to one end of the switch S218 and one end of the switch S219.

One of the two electrodes of the capacitor C213 is connected to one end of the switch S216 and one end of the switch S217. The other of the two electrodes of the capacitor C213 is connected to one end of the switch S21A and one end of the switch S21B.

One of the two electrodes of the capacitor C214 is connected to one end of the switch S218 and one end of the switch S219. The other of the two electrodes of the capacitor C214 is connected to one end of the switch S21C and one end of the switch S21D.

One of the two electrodes of the capacitor C215 is connected to one end of the switch S21A and one end of the switch S21B. The other of the two electrodes of the capacitor C215 is connected to one end of the switch S21E and one end of the switch S21F.

One of the two electrodes of the capacitor C216 is connected to one end of the switch S21C and one end of the switch S21D. The other of the two electrodes of the capacitor C216 is connected to one end of the switch S21G and one end of the switch S21H.

One of the two electrodes of the capacitor C217 is connected to one end of the switch S21E and one end of the switch S21F. The other of the two electrodes of the capacitor C217 is connected to one end of the switch S211 and one end of the switch S21J.

One of the two electrodes of the capacitor C218 is connected to one end of the switch S21G and one end of the switch S21H. The other of the two electrodes of the capacitor C218 is connected to one end of the switch S21K and one end of the switch S21L.

One of the two electrodes of the capacitor C219 is connected to one end of the switch S21I and one end of the switch S21J. The other of the two electrodes of the capacitor C219 is connected to one end of the switch S21M and one end of the switch S21N.

The capacitors C21A to C21F are smoothing capacitors that can be configured to hold and smooth the voltages (V11 to V16) at the nodes N11 to N16.

The capacitor C21A is connected between the node N11 and the ground. Specifically, one of the two electrodes of the capacitor C21A is connected to the node N11. On the other hand, the other of the two electrodes of the capacitor C21A is connected to the ground.

The capacitor C21B is connected between the nodes N11 and N12. Specifically, one of the two electrodes of the capacitor C21B is connected to the node N12. On the other hand, the other of the two electrodes of the capacitor C21B is connected to the node N11.

The capacitor C21C is connected between the nodes N12 and N13. Specifically, one of the two electrodes of the capacitor C21C is connected to the node N13. On the other hand, the other of the two electrodes of the capacitor C21C is connected to the node N12.

The capacitor C21D is connected between the nodes N13 and N14. Specifically, one of the two electrodes of the capacitor C21D is connected to the node N14. On the other hand, the other of the two electrodes of the capacitor C21D is connected to the node N13.

The capacitor C21E is connected between the nodes N14 and N15. Specifically, one of the two electrodes of the capacitor C21E is connected to the node N15. On the other hand, the other of the two electrodes of the capacitor C21E is connected to the node N14.

The capacitor C21F is connected between the nodes N15 and N16. Specifically, one of the two electrodes of the capacitor C21F is connected to the node N16. On the other hand, the other of the two electrodes of the capacitor C21F is connected to the node N15.

The switch S210 is connected between the capacitor C210 and the ground. Specifically, one end of the switch S210 is connected to one of the two electrodes of the capacitor C210. On the other hand, the other end of the switch S210 is connected to the ground.

The switch S211 is connected between the capacitor C210 and the node N11. Specifically, one end of the switch S211 is connected to one of the two electrodes of the capacitor C210. On the other hand, the other end of the switch S211 is connected to the node N11.

The switch S212 is connected between the capacitor C211 and the ground. Specifically, one end of the switch S212 is connected to one of the two electrodes of the capacitor C211. On the other hand, the other end of the switch S212 is connected to the ground.

The switch S213 is connected between the capacitor C211 and the node N11. Specifically, one end of the switch S213 is connected to one of the two electrodes of the capacitor C211. On the other hand, the other end of the switch S213 is connected to the node N11.

The switch S214 is connected between the capacitors C210 and C212 and the node N11. Specifically, one end of the switch S214 is connected to the other of the two electrodes of the capacitor C210 and one of the two electrodes of the capacitor C212. On the other hand, the other end of the switch S214 is connected to the node N11.

The switch S215 is connected between the capacitors C210 and C212 and the node N12. Specifically, one end of the switch S215 is connected to the other of the two electrodes of the capacitor C210 and one of the two electrodes of the capacitor C212. On the other hand, the other end of the switch S215 is connected to the node N12.

The switch S216 is connected between the capacitors C211 and C213 and the node N11. Specifically, one end of the switch S216 is connected to the other of the two electrodes of the capacitor C211 and one of the two electrodes of the capacitor C213. On the other hand, the other end of the switch S216 is connected to the node N11.

The switch S217 is connected between the capacitors C211 and C213 and the node N12. Specifically, one end of the switch S217 is connected to the other of the two electrodes of the capacitor C211 and one of the two electrodes of the capacitor C213. On the other hand, the other end of the switch S217 is connected to the node N12.

The switch S218 is connected between the capacitors C212 and C214 and the node N12. Specifically, one end of the switch S218 is connected to the other of the two electrodes of the capacitor C212 and one of the two electrodes of the capacitor C214. On the other hand, the other end of the switch S218 is connected to the node N12.

The switch S219 is connected between the capacitors C212 and C214 and the node N13. Specifically, one end of the switch S219 is connected to the other of the two electrodes of the capacitor C212 and one of the two electrodes of the capacitor C214. On the other hand, the other end of the switch S219 is connected to the node N13.

The switch S21A is connected between the capacitors C213 and C215 and the node N12. Specifically, one end of the switch S21A is connected to the other of the two electrodes of the capacitor C213 and one of the two electrodes of the capacitor C215. On the other hand, the other end of the switch S21A is connected to the node N12.

The switch S21B is connected between the capacitors C213 and C215 and the node N13. Specifically, one end of the switch S21B is connected to the other of the two electrodes of the capacitor C213 and one of the two electrodes of the capacitor C215. On the other hand, the other end of the switch S21B is connected to the node N13.

The switch S21C is connected between the capacitors C214 and C216 and the node N13. Specifically, one end of the switch S21C is connected to the other of the two electrodes of the capacitor C214 and one of the two electrodes of the capacitor C216. On the other hand, the other end of the switch S21C is connected to the node N13.

The switch S21D is connected between the capacitors C214 and C216 and the node N14. Specifically, one end of the switch S21D is connected to the other of the two electrodes of the capacitor C214 and one of the two electrodes of the capacitor C216. On the other hand, the other end of the switch S21D is connected to the node N14.

The switch S21E is connected between the capacitors C215 and C217 and the node N13. Specifically, one end of the switch S21E is connected to the other of the two electrodes of the capacitor C215 and one of the two electrodes of the capacitor C217. On the other hand, the other end of the switch S21E is connected to the node N13.

The switch S21F is connected between the capacitors C215 and C217 and the node N14. Specifically, one end of the switch S21F is connected to the other of the two electrodes of the capacitor C215 and one of the two electrodes of the capacitor C217. On the other hand, the other end of the switch S21F is connected to the node N14.

The switch S21G is connected between the capacitors C216 and C218 and the node N14. Specifically, one end of the switch S21G is connected to the other of the two electrodes of the capacitor C216 and one of the two electrodes of the capacitor C218. On the other hand, the other end of the switch S21G is connected to the node N14.

The switch S21H is connected between the capacitors C216 and C218 and the node N15. Specifically, one end of the switch S21H is connected to the other of the two electrodes of the capacitor C216 and one of the two electrodes of the capacitor C218. On the other hand, the other end of the switch S21H is connected to the node N15.

The switch S21I is connected between the capacitors C217 and C219 and the node N14. Specifically, one end of the switch S21I is connected to the other of the two electrodes of the capacitor C217 and one of the two electrodes of the capacitor C219. On the other hand, the other end of the switch S21I is connected to the node N14.

The switch S21J is connected between the capacitors C217 and C219 and the node N15. Specifically, one end of the switch S21J is connected to the other of the two electrodes of the capacitor C217 and one of the two electrodes of the capacitor C219. On the other hand, the other end of the switch S21J is connected to the node N15.

The switch S21K is connected between the capacitor C218 and the node N15. Specifically, one end of the switch S21K is connected to the other of the two electrodes of the capacitor C218. On the other hand, the other end of the switch S21K is connected to the node N15.

The switch S21L is connected between the capacitor C218 and the node N16. Specifically, one end of the switch S21L is connected to the other of the two electrodes of the capacitor C218. On the other hand, the other end of the switch S21L is connected to the node N16.

The switch S21M is connected between the capacitor C219 and the node N15. Specifically, one end of the switch S21M is connected to the other of the two electrodes of the capacitor C219. On the other hand, the other end of the switch S21M is connected to the node N15.

The switch S21N is connected between the capacitor C219 and the node N16. Specifically, one end of the switch S21N is connected to the other of the two electrodes of the capacitor C219. On the other hand, the other end of the switch S21N is connected to the node N16.

A first set of switches including the switches S210, S213, S214, S217, S218, S21B, S21C, S21F, S21G, S21J, S21K, and S21N, and a second set of switches including the switches S211, S212, S215, S216, S219, S21A, S21D, S21E, S21H, S21I, S21L, and S21M are mutually and reversely switched ON and OFF based on a control signal CS21 from the digital control circuit 60.

Specifically, in a first phase, the first set of switches are closed, and the second set of switches are opened. Thus, one of the two electrodes of the capacitor C210 is connected to the ground. The other of the two electrodes of the capacitor C210, one of the two electrodes of the capacitor C211, and one of the two electrodes of the capacitor C212 are connected to the node N11. The other of the two electrodes of the capacitor C211, the other of the two electrodes of the capacitor C212, one of the two electrodes of the capacitor C213, and one of the two electrodes of the capacitor C214 are connected to the node N12. The other of the two electrodes of the capacitor C213, the other of the two electrodes of the capacitor C214, one of the two electrodes of the capacitor C215, and one of the two electrodes of the capacitor C216 are connected to the node N13. The other of the two electrodes of the capacitor C215, the other of the two electrodes of the capacitor C216, one of the two electrodes of the capacitor C217, and one of the two electrodes of the capacitor C218 are connected to the node N14. The other of the two electrodes of the capacitor C217, the other of the two electrodes of the capacitor C218, and one of the two electrodes of the capacitor C219 are connected to the node N15. The other of the two electrodes of the capacitor C219 is connected to the node N16.

Conversely, in a second phase, the first set of switches are opened, and the second set of switches are closed. Thus, one of the two electrodes of the capacitor C211 is connected to the ground. One of the two electrodes of the capacitor C210, the other of the two electrodes of the capacitor C211, and one of the two electrodes of the capacitor C213 are connected to the node N11. The other of the two electrodes of the capacitor C210, one of the two electrodes of the capacitor C212, the other of the two electrodes of the capacitor C213, and one of the two electrodes of the capacitor C215 are connected to the node N12. The other of the two electrodes of the capacitor C212, one of the two electrodes of the capacitor C214, the other of the two electrodes of the capacitor C215, and one of the two electrodes of the capacitor C217 are connected to the node N13. The other of the two electrodes of the capacitor C214, one of the two electrodes of the capacitor C216, the other of the two electrodes of the capacitor C217, and one of the two electrodes of the capacitor C219 are connected to the node N14. The other of the two electrodes of the capacitor C216, one of the two electrodes of the capacitor C218, and the other of the two electrodes of the capacitor C219 are connected to the node N15. The other of the two electrodes of the capacitor C218 is connected to the node N16.

By repeating the first phase and the second phase, the capacitors C210 to C219 can be charged and discharged complementarily. For example, charging from the capacitors C210, C212, C214, C216, and C218 to the capacitors C21A to C21F is performed in one of the first phase and the second phase, and charging from the capacitors C211, C213, C215, C217, and C219 to the capacitors C21A to C21F is performed in the other of the first phase and the second phase. In other words, since the capacitors C21A to C21F are constantly charged from any one of the capacitors C210 to C219, even when a current flows at a high speed from any one of the nodes N11 to N16 to the supply modulator 31 or 32, electric charges are replenished at a high speed to any one of the nodes N11 to N16, so that the potential fluctuation of the nodes N11 to N16 can be suppressed.

By operating in such a manner, the switched-capacitor circuit 21 can maintain substantially equal voltages at both ends of each of the capacitors C21A to C21F. Specifically, V11 to V16 satisfying (V16−V15):(V15−V14):(V14−V13):(V13−V12):(V12−V11):(V11−VG)=1:1:1:1:1:1 are maintained at the six nodes N11 to N16 labeled V11 to V16. For example, when the regulated voltage supplied from the pre-regulator circuit 10 is 5 V, the switched-capacitor circuit 21 can be configured to generate (1 V, 2 V, 3 V, 4 V, 5 V, 6 V) as the first plurality of discrete voltages (V11 to V16).

It is noted that (V16−V15):(V15−V14):(V14−V13):(V13−V12):(V12−V11):(V11−VG) are not limited to 1:1:1:1:1:1, but can be designed to be any ratio (for example, 1:2:3:4:5:6, 6:5:4:3:2:1, or the like) according to various exemplary aspects.

### [1.2.3 Circuit Configuration of Supply Modulator 31]

Next, the circuit configuration of the supply modulator 31 included in the tracker circuit 1 will be described with reference to FIG. 4.

The supply modulator 31 includes input terminals T311 to T316, switches S311 to S316, and an output terminal T317.

The input terminals T311 to T316 are terminals for receiving the first plurality of discrete voltages (V11 to V16) generated by the switched-capacitor circuit 21. The input terminals T311 to T316 are externally connected to the output terminals T211 to T216 of the switched-capacitor circuit 21, respectively, and internally connected to the switches S311 to S316, respectively.

The output terminal T317 is a terminal for supplying the power supply voltage (Vcc1) to the power amplifier 2a. The output terminal T317 is externally connected to the power amplifier 2a and internally connected to the switches S311 to S316.

The switch S311 is connected between the input terminal T311 and the output terminal T317. In such a connection configuration, the switch S311 can switch the connection and disconnection between the input terminal T311 and the output terminal T317 by being switched ON and OFF by a control signal CS31 from the digital control circuit 60.

The switch S312 is connected between the input terminal T312 and the output terminal T317. In such a connection configuration, the switch S312 can switch the connection and disconnection between the input terminal T312 and the output terminal T317 by being switched ON and OFF by the control signal CS31 from the digital control circuit 60.

The switch S313 is connected between the input terminal T313 and the output terminal T317. In such a connection configuration, the switch S313 can switch the connection and disconnection between the input terminal T313 and the output terminal T317 by being switched ON and OFF by the control signal CS31 from the digital control circuit 60.

The switch S314 is connected between the input terminal T314 and the output terminal T317. In such a connection configuration, the switch S314 can switch the connection and disconnection between the input terminal T314 and the output terminal T317 by being switched ON and OFF by the control signal CS31 from the digital control circuit 60.

The switch S315 is connected between the input terminal T315 and the output terminal T317. In such a connection configuration, the switch S315 can switch the connection and disconnection between the input terminal T315 and the output terminal T317 by being switched ON and OFF by the control signal CS31 from the digital control circuit 60.

The switch S316 is connected between the input terminal T316 and the output terminal T317. In such a connection configuration, the switch S316 can switch the connection and disconnection between the input terminal T316 and the output terminal T317 by being switched ON and OFF by the control signal CS31 from the digital control circuit 60.

In the present embodiment, the switches S311 to S316 are controlled so as to be turned on exclusively. In other words, the switches S311 to S316 are controlled so that only one of the switches S311 to S316 is closed and the remainder of the switches S311 to S316 are all opened. Thus, the supply modulator 31 can supply one voltage selected from the first plurality of discrete voltages (V11 to V16) to the power amplifier 2a as the power supply voltage (Vcc1).

It is noted that the configuration of the supply modulator 31 shown in FIG. 4 is an example and is not limited to such an example. In particular, the switches S311 to S316 may have any configuration and may be controlled in any manner as long as at least one of the six input terminals T311 to T316 is selectively connected to the output terminal T317. For example, two of the switches S311 to S316 may be closed and the remainder of the switches S311 to S316 may be opened.

### [1.2.4 Circuit Configuration of Supply Modulator 32]

Next, the circuit configuration of the supply modulator 32 included in the tracker circuit 1 will be described with reference to FIG. 4.

The supply modulator 32 includes input terminals T321 to T326, switches S321 to S326, and an output terminal T327. The circuit configuration of the supply modulator 32 is the same as that of the supply modulator 31 except that the output terminal T327 is externally connected to the power amplifier 2b. The details of the circuit configuration of the supply modulator 32 will be described below.

The input terminals T321 to T326 are terminals for receiving the first plurality of discrete voltages (V11 to V16) generated by the switched-capacitor circuit 21. The input terminals T321 to T326 are externally connected to the output terminals T211 to T216 of the switched-capacitor circuit 21, respectively, and are internally connected to the switches S321 to S326, respectively.

The output terminal T327 is a terminal for supplying the power supply voltage (Vcc2) to the power amplifier 2b. The output terminal T327 is externally connected to the power amplifier 2b and internally connected to the switches S321 to S326.

The switch S321 is connected between the input terminal T321 and the output terminal T327. In such a connection configuration, the switch S321 can switch the connection and disconnection between the input terminal T321 and the output terminal T327 by being switched ON and OFF by a control signal CS32 from the digital control circuit 60.

The switch S322 is connected between the input terminal T322 and the output terminal T327. In such a connection configuration, the switch S322 can switch the connection and disconnection between the input terminal T322 and the output terminal T327 by being switched ON and OFF by the control signal CS32 from the digital control circuit 60.

The switch S323 is connected between the input terminal T323 and the output terminal T327. In such a connection configuration, the switch S323 can switch the connection and disconnection between the input terminal T323 and the output terminal T327 by being switched ON and OFF by the control signal CS32 from the digital control circuit 60.

The switch S324 is connected between the input terminal T324 and the output terminal T327. In such a connection configuration, the switch S324 can switch the connection and disconnection between the input terminal T324 and the output terminal T327 by being switched ON and OFF by the control signal CS32 from the digital control circuit 60.

The switch S325 is connected between the input terminal T325 and the output terminal T327. In such a connection configuration, the switch S325 can switch the connection and disconnection between the input terminal T325 and the output terminal T327 by being switched ON and OFF by the control signal CS32 from the digital control circuit 60.

The switch S326 is connected between the input terminal T326 and the output terminal T327. In such a connection configuration, the switch S326 can switch the connection and disconnection between the input terminal T326 and the output terminal T327 by being switched ON and OFF by the control signal CS32 from the digital control circuit 60.

In the present embodiment, the switches S321 to S326 are controlled so as to be turned on exclusively. In other words, the switches S321 to S326 are controlled so that only one of the switches S321 to S326 is closed and the remainder of the switches S321 to S326 are all opened. Thus, the supply modulator 32 can supply one voltage selected from the first plurality of discrete voltages (V11 to V16) to the power amplifier 2b as the power supply voltage (Vcc2).

It is noted that the configuration of the supply modulator 32 shown in FIG. 4 is an example and is not limited to such an example. In particular, the switches S321 to S326 may have any configuration and may be controlled in any manner as long as at least one of the six input terminals T321 to T326 is selectively connected to the output terminal T327. For example, two of the switches S321 to S326 may be closed and the remainder of the switches S321 to S326 may be opened.

### [1.2.5 Circuit Configuration of Switched-Capacitor Circuit 22]

Next, the circuit configuration of the switched-capacitor circuit 22 included in the tracker circuit 1 will be described with reference to FIG. 5.

The switched-capacitor circuit 22 differs from the switched-capacitor circuit 21 in that the input terminal T220 is internally connected to a node N26 instead of a node N25. Thus, the switched-capacitor circuit 22 is configured to generate a second plurality of discrete voltages (V21 to V26) different from the first plurality of discrete voltages (V11 to V16) generated by the switched-capacitor circuit 21.

In the present embodiment, the highest voltage (V26) among the second plurality of discrete voltages (V21 to V26) is lower than the highest voltage (V16) among the first plurality of discrete voltages (V11 to V16). Further, the average ({(V26−V25)+(V25−V24)+(V24−V23)+(V23−V22)+(V22−V21)}/5) of the level differences between adjacent voltages of the second plurality of discrete voltages (V21 to V26) is smaller than the average ({(V16−V15)+(V15−V14)+(V14−V13)+(V13−V12)+(V12−V11)}/5) of the level differences between adjacent voltages of the first plurality of discrete voltages (V11 to V16).

The circuit configuration of the switched-capacitor circuit 22 is substantially the same as that of the switched-capacitor circuit 21. The details of the circuit configuration of the switched-capacitor circuit 22 will be described below.

The switched-capacitor circuit 22 has a ladder type circuit configuration. Specifically, the switched-capacitor circuit 22 includes capacitors C220 to C22F, switches S220 to S22N, the input terminal T220, and output terminals T221 to T226. Energy and electric charges are inputted from the pre-regulator circuit 10 to the node N26 via the input terminal T220 and are extracted from nodes N21 to N26 to the supply modulator 33 via the output terminals T221 to T226.

The input terminal T220 is a terminal for receiving the regulated voltage from the pre-regulator circuit 10. The input terminal T220 is externally connected to the pre-regulator circuit 10 and internally connected to the node N26.

The output terminal T221 is a terminal for supplying a voltage (V21) of the second plurality of discrete voltages (V21 to V26) to the supply modulator 33. The output terminal T221 is externally connected to the supply modulator 33 and internally connected to the node N21.

The output terminal T222 is a terminal for supplying a voltage (V22) of the second plurality of discrete voltages (V21 to V26) to the supply modulator 33. The output terminal T222 is externally connected to the supply modulator 33 and internally connected to the node N22.

The output terminal T223 is a terminal for supplying a voltage (V23) of the second plurality of discrete voltages (V21 to V26) to the supply modulator 33. The output terminal T223 is externally connected to the supply modulator 33 and internally connected to the node N23.

The output terminal T224 is a terminal for supplying a voltage (V24) of the second plurality of discrete voltages (V21 to V26) to the supply modulator 33. The output terminal T224 is externally connected to the supply modulator 33 and internally connected to the node N24.

The output terminal T225 is a terminal for supplying a voltage (V25) of the second plurality of discrete voltages (V21 to V26) to the supply modulator 33. The output terminal T225 is externally connected to the supply modulator 33 and internally connected to the node N25.

The output terminal T226 is a terminal for supplying a voltage (V26) of the second plurality of discrete voltages (V21 to V26) to the supply modulator 33. The output terminal T226 is externally connected to the supply modulator 33 and internally connected to the node N26. The output terminal T226 may be integrated with the input terminal T220.

The capacitors C220 to C229 can be flying capacitors (sometimes referred to as transfer capacitors) and can be configured to lower the regulated voltage (V25) supplied from the pre-regulator circuit 10. Specifically, the capacitors C220 to C229 transfer electric charges between the capacitors C220 to C229 and the nodes N21 to N26 and the ground so that V21 to V26 satisfying (V26−V25):(V25−V24):(V24−V23):(V23−V22):(V22−V21):(V21−VG)=1:1:1:1:1:1 and V26>V25>V24>V23>V22>V21>VG are maintained at the six nodes N21 to N26.

One of the two electrodes of the capacitor C220 is connected to one end of the switch S220 and one end of the switch S221. The other of the two electrodes of the capacitor C220 is connected to one end of the switch S224 and one end of the switch S225.

One of the two electrodes of the capacitor C221 is connected to one end of the switch S222 and one end of the switch S223. The other of the two electrodes of the capacitor C221 is connected to one end of the switch S226 and one end of the switch S227.

One of the two electrodes of the capacitor C222 is connected to one end of the switch S224 and one end of the switch S225. The other of the two electrodes of the capacitor C222 is connected to one end of the switch S228 and one end of the switch S229.

One of the two electrodes of the capacitor C223 is connected to one end of the switch S226 and one end of the switch S227. The other of the two electrodes of the capacitor C223 is connected to one end of the switch S22A and one end of the switch S22B.

One of the two electrodes of the capacitor C224 is connected to one end of the switch S228 and one end of the switch S229. The other of the two electrodes of the capacitor C224 is connected to one end of the switch S22C and one end of the switch S22D.

One of the two electrodes of the capacitor C225 is connected to one end of the switch S22A and one end of the switch S22B. The other of the two electrodes of the capacitor C225 is connected to one end of the switch S22E and one end of the switch S22F.

One of the two electrodes of the capacitor C226 is connected to one end of the switch S22C and one end of the switch S22D. The other of the two electrodes of the capacitor C226 is connected to one end of the switch S22G and one end of the switch S22H.

One of the two electrodes of the capacitor C227 is connected to one end of the switch S22E and one end of the switch S22F. The other of the two electrodes of the capacitor C227 is connected to one end of the switch S221 and one end of the switch S22J.

One of the two electrodes of the capacitor C228 is connected to one end of the switch S22G and one end of the switch S21H. The other of the two electrodes of the capacitor C228 is connected to one end of the switch S22K and one end of the switch S22L.

One of the two electrodes of the capacitor C229 is connected to one end of the switch S221 and one end of the switch S22J. The other of the two electrodes of the capacitor C229 is connected to one end of the switch S22M and one end of the switch S22N.

The capacitors C22A to C22F can be smoothing capacitors that are configured to hold and smooth the voltages (V21 to V26) at the nodes N21 to N26.

The capacitor C22A is connected between the node N21 and the ground. Specifically, one of the two electrodes of the capacitor C22A is connected to the node N21. On the other hand, the other of the two electrodes of the capacitor C22A is connected to the ground.

The capacitor C22B is connected between the nodes N21 and N22. Specifically, one of the two electrodes of the capacitor C22B is connected to the node N22. On the other hand, the other of the two electrodes of the capacitor C22B is connected to the node N21.

The capacitor C22C is connected between the nodes N22 and N23. Specifically, one of the two electrodes of the capacitor C22C is connected to the node N23. On the other hand, the other of the two electrodes of the capacitor C22C is connected to the node N22.

The capacitor C22D is connected between the nodes N23 and N24. Specifically, one of the two electrodes of the capacitor C22D is connected to the node N24. On the other hand, the other of the two electrodes of the capacitor C22D is connected to the node N23.

The capacitor C22E is connected between the nodes N24 and N25. Specifically, one of the two electrodes of the capacitor C22E is connected to the node N25. On the other hand, the other of the two electrodes of the capacitor C22E is connected to the node N24.

The capacitor C22F is connected between the nodes N25 and N26. Specifically, one of the two electrodes of the capacitor C22F is connected to the node N26. On the other hand, the other of the two electrodes of the capacitor C22F is connected to the node N25.

The switch S220 is connected between the capacitor C220 and the ground. Specifically, one end of the switch S220 is connected to one of the two electrodes of the capacitor C220. On the other hand, the other end of the switch S220 is connected to the ground.

The switch S221 is connected between the capacitor C220 and the node N21. Specifically, one end of the switch S221 is connected to one of the two electrodes of the capacitor C220. On the other hand, the other end of the switch S221 is connected to the node N21.

The switch S222 is connected between the capacitor C221 and the ground. Specifically, one end of the switch S222 is connected to one of the two electrodes of the capacitor C221. On the other hand, the other end of the switch S222 is connected to the ground.

The switch S223 is connected between the capacitor C221 and the node N21. Specifically, one end of the switch S223 is connected to one of the two electrodes of the capacitor C221. On the other hand, the other end of the switch S223 is connected to the node N21.

The switch S224 is connected between the capacitors C220 and C222 and the node N21. Specifically, one end of the switch S224 is connected to the other of the two electrodes of the capacitor C220 and one of the two electrodes of the capacitor C222. On the other hand, the other end of the switch S224 is connected to the node N21.

The switch S225 is connected between the capacitors C220 and C222 and the node N22. Specifically, one end of the switch S225 is connected to the other of the two electrodes of the capacitor C220 and one of the two electrodes of the capacitor C222. On the other hand, the other end of the switch S225 is connected to the node N22.

The switch S226 is connected between the capacitors C221 and C223 and the node N21. Specifically, one end of the switch S226 is connected to the other of the two electrodes of the capacitor C221 and one of the two electrodes of the capacitor C223. On the other hand, the other end of the switch S226 is connected to the node N21.

The switch S227 is connected between the capacitors C221 and C223 and the node N22. Specifically, one end of the switch S227 is connected to the other of the two electrodes of the capacitor C221 and one of the two electrodes of the capacitor C223. On the other hand, the other end of the switch S227 is connected to the node N22.

The switch S228 is connected between the capacitors C222 and C224 and the node N22. Specifically, one end of the switch S228 is connected to the other of the two electrodes of the capacitor C222 and one of the two electrodes of the capacitor C224. On the other hand, the other end of the switch S228 is connected to the node N22.

The switch S229 is connected between the capacitors C222 and C224 and the node N23. Specifically, one end of the switch S229 is connected to the other of the two electrodes of the capacitor C222 and one of the two electrodes of the capacitor C224. On the other hand, the other end of the switch S229 is connected to the node N23.

The switch S22A is connected between the capacitors C223 and C225 and the node N22. Specifically, one end of the switch S22A is connected to the other of the two electrodes of the capacitor C223 and one of the two electrodes of the capacitor C225. On the other hand, the other end of the switch S22A is connected to the node N22.

The switch S22B is connected between the capacitors C223 and C225 and the node N23. Specifically, one end of the switch S22B is connected to the other of the two electrodes of the capacitor C223 and one of the two electrodes of the capacitor C225. On the other hand, the other end of the switch S22B is connected to the node N23.

The switch S22C is connected between the capacitors C224 and C226 and the node N23. Specifically, one end of the switch S22C is connected to the other of the two electrodes of the capacitor C224 and one of the two electrodes of the capacitor C226. On the other hand, the other end of the switch S22C is connected to the node N23.

The switch S22D is connected between the capacitors C224 and C226 and the node N24. Specifically, one end of the switch S22D is connected to the other of the two electrodes of the capacitor C224 and one of the two electrodes of the capacitor C226. On the other hand, the other end of the switch S22D is connected to the node N24.

The switch S22E is connected between the capacitors C225 and C227 and the node N23. Specifically, one end of the switch S22E is connected to the other of the two electrodes of the capacitor C225 and one of the two electrodes of the capacitor C227. On the other hand, the other end of the switch S22E is connected to the node N23.

The switch S22F is connected between the capacitors C225 and C227 and the node N24. Specifically, one end of the switch S22F is connected to the other of the two electrodes of the capacitor C225 and one of the two electrodes of the capacitor C227. On the other hand, the other end of the switch S22F is connected to the node N24.

The switch S22G is connected between the capacitors C226 and C228 and the node N24. Specifically, one end of the switch S22G is connected to the other of the two electrodes of the capacitor C226 and one of the two electrodes of the capacitor C228. On the other hand, the other end of the switch S22G is connected to the node N24.

The switch S22H is connected between the capacitors C226 and C228 and the node N25. Specifically, one end of the switch S22H is connected to the other of the two electrodes of the capacitor C226 and one of the two electrodes of the capacitor C228. On the other hand, the other end of the switch S22H is connected to the node N25.

The switch S221 is connected between the capacitors C227 and C229 and the node N24. Specifically, one end of the switch S22I is connected to the other of the two electrodes of the capacitor C227 and one of the two electrodes of the capacitor C229. On the other hand, the other end of the switch S221 is connected to the node N24.

The switch S22J is connected between the capacitors C227 and C229 and the node N25. Specifically, one end of the switch S22J is connected to the other of the two electrodes of the capacitor C227 and one of the two electrodes of the capacitor C229. On the other hand, the other end of the switch S22J is connected to the node N25.

The switch S22K is connected between the capacitor C228 and the node N25. Specifically, one end of the switch S22K is connected to the other of the two electrodes of the capacitor C228. On the other hand, the other end of the switch S22K is connected to the node N25.

The switch S22L is connected between the capacitor C228 and the node N26. Specifically, one end of the switch S22L is connected to the other of the two electrodes of the capacitor C228. On the other hand, the other end of the switch S22L is connected to the node N26.

The switch S22M is connected between the capacitor C229 and the node N25. Specifically, one end of the switch S22M is connected to the other of the two electrodes of the capacitor C229. On the other hand, the other end of the switch S22M is connected to the node N25.

The switch S22N is connected between the capacitor C229 and the node N26. Specifically, one end of the switch S22N is connected to the other of the two electrodes of the capacitor C229. On the other hand, the other end of the switch S22N is connected to the node N26.

A first set of switches including the switches S220, S223, S224, S227, S228, S22B, S22C, S22F, S22G, S22J, S22K, and S22N, and a second set of switches including the switches S221, S222, S225, S226, S229, S22A, S22D, S22E, S22H, S221, S22L, and S22M are mutually reversely switched ON and OFF based on a control signal CS22 from the digital control circuit 60.

Specifically, in a first phase, the first set of switches are closed and the second set of switches are opened. Thus, one of the two electrodes of the capacitor C220 is connected to the ground. The other of the two electrodes of the capacitor C220, one of the two electrodes of the capacitor C221, and one of the two electrodes of the capacitor C222 are connected to the node N21. The other of the two electrodes of the capacitor C221, the other of the two electrodes of the capacitor C222, one of the two electrodes of the capacitor C223, and one of the two electrodes of the capacitor C224 are connected to the node N22. The other of the two electrodes of the capacitor C223, the other of the two electrodes of the capacitor C224, one of the two electrodes of the capacitor C225, and one of the two electrodes of the capacitor C226 are connected to the node N23. The other of the two electrodes of the capacitor C225, the other of the two electrodes of the capacitor C226, one of the two electrodes of the capacitor C227, and one of the two electrodes of the capacitor C228 are connected to the node N24. The other of the two electrodes of the capacitor C227, the other of the two electrodes of the capacitor C228, and one of the two electrodes of the capacitor C229 are connected to the node N25. The other of the two electrodes of the capacitor C229 is connected to the node N26.

Conversely, in a second phase, the first set of switches are opened, and the second set of switches are closed. Thus, one of the two electrodes of the capacitor C221 is connected to the ground. One of the two electrodes of the capacitor C220, the other of the two electrodes of the capacitor C221, and one of the two electrodes of the capacitor C223 are connected to the node N21. The other of the two electrodes of the capacitor C220, one of the two electrodes of the capacitor C222, the other of the two electrodes of the capacitor C223, and one of the two electrodes of the capacitor C225 are connected to the node N22. The other of the two electrodes of the capacitor C222, one of the two electrodes of the capacitor C224, the other of the two electrodes of the capacitor C225, and one of the two electrodes of the capacitor C227 are connected to the node N23. The other of the two electrodes of the capacitor C224, one of the two electrodes of the capacitor C226, the other of the two electrodes of the capacitor C227, and one of the two electrodes of the capacitor C229 are connected to the node N24. The other of the two electrodes of the capacitor C226, one of the two electrodes of the capacitor C228, and the other of the two electrodes of the capacitor C229 are connected to the node N25. The other of the two electrodes of the capacitor C228 is connected to the node N26.

By repeating the first phase and the second phase, the capacitors C220 to C229 can be charged and discharged complementarily. For example, charging from the capacitors C220, C222, C224, C226 and C228 to the capacitors C22A to C22F is performed in one of the first phase and the second phase, and charging from the capacitors C221, C223, C225, C227 and C229 to the capacitors C22A to C22F is performed in the other of the first phase and the second phase. In other words, since the capacitors C22A to C22F are constantly charged from any one of the capacitors C220 to C229, even when a current flows at a high speed from any one of the nodes N21 to N26 to the supply modulator 33, electric charges are replenished at a high speed to any one of the nodes N21 to N26, so that the potential fluctuations of the nodes N21 to N26 can be suppressed.

By operating in such a manner, the switched-capacitor circuit 22 can maintain substantially equal voltages at both ends of each of the capacitors C22A to C22F. Specifically, V21 to V26 satisfying (V26−V25):(V25−V24):(V24−V23):(V23−V22):(V22−V21):(V21−VG)=1:1:1:1:1:1 are maintained at the six nodes N21 to N26 labeled V21 to V26. For example, when the regulated voltage supplied from the pre-regulator circuit 10 is 5 V, the switched-capacitor circuit 22 can be configured to generate (0.8 V, 1.7 V, 2.5 V, 3.3 V, 4.2 V, 5 V) as the second plurality of discrete voltages (V21 to V26).

It is noted that (V26−V25):(V25−V24):(V24−V23):(V23−V22):(V22−V21):(V21−VG) are not limited to 1:1:1:1:1:1 and can be designed to be any ratio (for example, 1:2:3:4:5:6, 6:5:4:3:2:1, or the like) according to various exemplary aspects.

### [1.2.6 Circuit Configuration of Supply Modulator 33]

Next, the circuit configuration of the supply modulator 33 included in the tracker circuit 1 will be described with reference to FIG. 5.

The supply modulator 33 includes input terminals T331 to T336, switches S331 to S336, and an output terminal T337. The circuit configuration of the supply modulator 33 is the same as that of the supply modulator 31 except that the input terminals T331 to T336 are externally connected to the switched-capacitor circuit 22 and the output terminal T337 is externally connected to the power amplifier 2c. The details of the circuit configuration of the supply modulator 33 will be described below.

The input terminals T331 to T336 are terminals for receiving the second plurality of discrete voltages (V21 to V26) generated by the switched-capacitor circuit 22. The input terminals T331 to T336 are externally connected to output terminals T221 to T226 of the switched-capacitor circuit 22, respectively, and internally connected to the switches S331 to S336, respectively.

The output terminal T337 is a terminal for supplying the power supply voltage (Vcc3) to the power amplifier 2c. The output terminal T337 is externally connected to the power amplifier 2c and internally connected to the switches S331 to S336.

The switch S331 is connected between the input terminal T331 and the output terminal T337. In such a connection configuration, the switch S331 can switch the connection and disconnection between the input terminal T331 and the output terminal T337 by being switched ON and OFF by a control signal CS33 from the digital control circuit 60.

The switch S332 is connected between the input terminal T332 and the output terminal T337. In such a connection configuration, the switch S332 can switch the connection and disconnection between the input terminal T332 and the output terminal T337 by being switched ON and OFF by the control signal CS33 from the digital control circuit 60.

The switch S333 is connected between the input terminal T333 and the output terminal T337. In such a connection configuration, the switch S333 can switch the connection and disconnection between the input terminal T333 and the output terminal T337 by being switched ON and OFF by the control signal CS33 from the digital control circuit 60.

The switch S334 is connected between the input terminal T334 and the output terminal T337. In such a connection configuration, the switch S334 can switch the connection and disconnection between the input terminal T334 and the output terminal T337 by being switched ON and OFF by the control signal CS33 from the digital control circuit 60.

The switch S335 is connected between the input terminal T335 and the output terminal T337. In such a connection configuration, the switch S335 can switch the connection and disconnection between the input terminal T335 and the output terminal T337 by being switched ON and OFF by the control signal CS33 from the digital control circuit 60.

The switch S336 is connected between the input terminal T336 and the output terminal T337. In such a connection configuration, the switch S336 can switch the connection and disconnection between the input terminal T336 and the output terminal T337 by being switched ON and OFF by the control signal CS33 from the digital control circuit 60.

In the present embodiment, the switches S331 to S336 are controlled so as to be turned on exclusively. In other words, the switches S331 to S336 are controlled so that only one of the switches S331 to S336 is closed and the remainder of the switches S331 to S336 are all opened. Thus, the supply modulator 33 can supply one voltage selected from the second plurality of discrete voltages (V21 to V26) to the power amplifier 2c as the power supply voltage (Vcc3).

It is noted that the configuration of the supply modulator 33 shown in FIG. 5 is an example and is not limited to such an example. In particular, the switches S331 to S336 may have any configuration and may be controlled in any manner as long as at least one of the six input terminals T331 to T336 is selectively connected to the output terminal T337. For example, two of the switches S331 to S336 may be closed and the remainder of the switches S331 to S336 may be opened.

### [1.2.7 Circuit Configuration of Digital Control Circuit 60]

Next, the circuit configuration of the digital control circuit 60 included in the tracker circuit 1 will be described with reference to FIG. 5. The digital control circuit 60 includes a first controller 61 and a second controller 62.

The first controller 61 can be configured tro process a digital control signal based on a serial data transmission standard supplied from the RFIC 4 to generate control signals CS10, CS21, and CS22 for controlling the pre-regulator circuit 10 and the switched-capacitor circuits 21 and 22. In the present embodiment, a digital control signal (a clock signal (CLK) and a data signal (DATA)) of a source synchronization method can be configured as the digital control signal based on the serial data transmission standard. Incidentally, a digital control signal of a clock embedding method may alternatively be used as the digital control signal based on the serial data transmission standard.

The second controller 62 processes the digital control signal based on the parallel data transmission standard supplied from the RFIC 4 to generate the control signals CS31 to CS33 for controlling the supply modulators 31 to 33 in a D-ET mode. In the present embodiment, DCL (digital control level) signals (DCL1 to DCL3) can be configured as the digital control signal based on the parallel data transmission standard.

The DCL signals (DCL1 to DCL3) are generated based on the envelope signals of the radio frequency signals amplified by the power amplifiers 2a to 2c and are each composed of three-bit signals. Each of the first plurality of discrete voltages (V11 to V16) and the second plurality of discrete voltages (V21 to V26) is represented by a combination of the three-bit signals. For example, the first plurality of discrete voltages (V11 to V16) are represented by “000”, “001”, “010”, “011”, “100”, and “101”, respectively. Further, for example, the second plurality of discrete voltages (V21 to V26) are represented by “000”, “001”, “010”, “011”, “100”, and “101”, respectively. A gray code may be used to represent the voltage level.

### [1.3 Amplification Method]

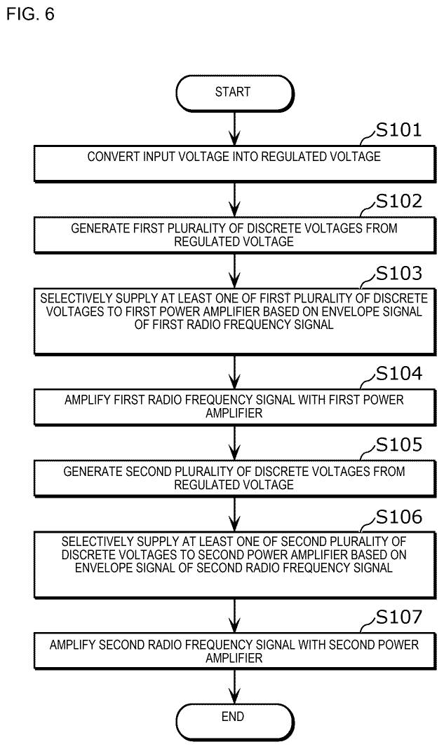

Next, an amplification method according to the present embodiment will be described with reference to FIG. 6. FIG. 6 is a flowchart showing an amplification method according to the present embodiment.

First, the pre-regulator circuit 10 converts the input voltage from the DC power source 6 into the regulated voltage (S101). The switched-capacitor circuit 21 generates the first plurality of discrete voltages (V11 to V16) from the regulated voltage (S102). The supply modulator 31 and/or the supply modulator 32 selectively supplies at least one of the first plurality of discrete voltages (V11 to V16) to the power amplifier 2a and/or the power amplifier 2b based on the envelope signal of the Sub6 signal of the cellular network (S103). The power amplifier 2a and/or the power amplifier 2b uses the voltage (Vcc1) and/or the voltage (Vcc2) supplied from the supply modulator 31 and/or the supply modulator 32 to amplify the Sub6 signal of the cellular network (S104).

The switched-capacitor circuit 22 generates the second plurality of discrete voltages (V21 to V26) from the regulated voltage (S105). The supply modulator 33 selectively supplies at least one of the second plurality of discrete voltages (V21 to V26) to the power amplifier 2c based on the envelope signal of the WLAN signal (S106). The power amplifier 2c uses the voltage (Vcc3) supplied from the supply modulator 33 to amplify the WLAN signal (S107).

### [1.4 Mounting Example of Tracker Circuit 1]

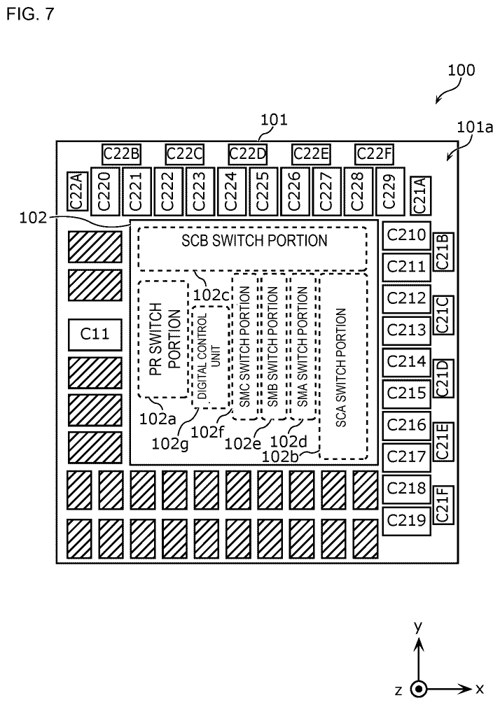

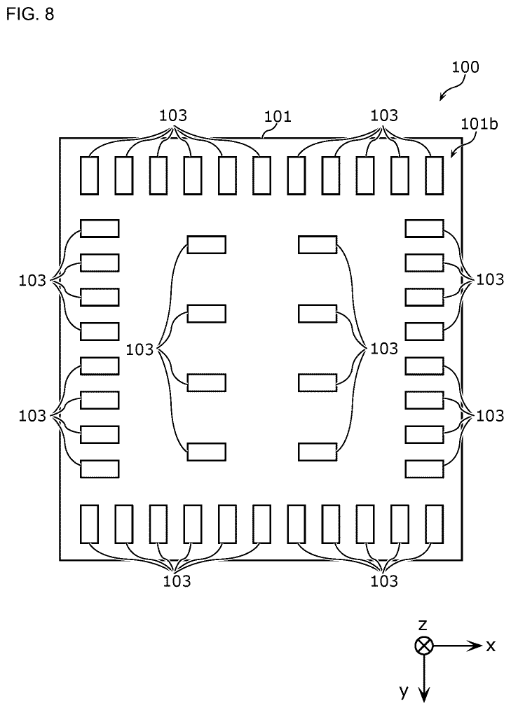

Next, a tracker module 100, which is a mounting example of the tracker circuit 1, will be described with reference to FIGS. 7 and 8. FIG. 7 is a plan view of the tracker module 100 according to the present embodiment. FIG. 8 is a bottom view of the tracker module 100 according to the present embodiment. Note that, in FIG. 7, labels each representing a code (such as “C210”) are attached to the corresponding components on a module laminate 101, and labels each representing a function (such as “SCA switch portion”) indicated by a broken line are attached to the corresponding functional regions in an integrated circuit 102. However, it is noted that these labels do not have to be attached to the actual components or the integrated circuit 102. Also, in FIG. 7, hatched components represent optional components that may be omitted according to variations of the present embodiment.

The tracker module 100 includes the module laminate 101 on which the tracker circuit 1 shown in FIG. 2 is mounted. The module laminate 101 has main surfaces 101a and 101b facing each other. Via conductors, wiring lines, and ground planes are formed in the module laminate 101 and on the main surface 101a.

Examples of those that can be used as the module laminate 101 include, but are not limited to, an LTCC (Low Temperature Co-fired Ceramics) substrate or an HTCC (High Temperature Co-fired Ceramics) substrate having a multilayer structure formed by stacking a plurality of dielectric layers, a component-embedded board, a substrate having an RDL (redistribution layer), and a printed circuit board.

The integrated circuit 102, the capacitor C11 included in the pre-regulator circuit 10, and the capacitors C210 to C21F and C220 to C22F included in the switched-capacitor circuits 21 and 22 are disposed on the main surface 101a of the module laminate 101. Note that, in the present embodiment, the power inductor L11 included in the pre-regulator circuit 10 is not disposed on the module laminate 101 but may be disposed on the module laminate 101.

The integrated circuit 102 includes a PR switch portion 102a, an SCA switch portion 102b, an SCB switch portion 102c, an SMA switch portion 102d, an SMB switch portion 102e, an SMC switch portion 102f, and a digital control unit 102g. The PR switch portion 102a includes the switches S11 to S14. The SCA switch portion 102b includes the switches S210 to S21N. The SCB switch portion 102c includes the switches S220 to S22N. The SMA switch portion 102d includes the switches S311 to S316. The SMB switch portion 102e includes the switches S321 to S326. The SMC switch portion 102f includes the switches S331 to S336. The digital control unit 102g includes the first controller 61 and the second controller 62.

FIG. 7 shows an example in which the PR switch portion 102a, the SCA switch portion 102b, the SCB switch portion 102c, the SMA switch portion 102d, the SMB switch portion 102e, the SMC switch portion 102f, and the digital control unit 102g are included in one integrated circuit 102. However, it is noted that the exemplary aspects of the present disclosure are not limited to such an example. For example, the PR switch portion 102a, the SCA switch portion 102b, the SCB switch portion 102c, the SMA switch portion 102d, the SMB switch portion 102e, the SMC switch portion 102f, and the digital control unit 102g may be individually included in a plurality of integrated circuits. Further, for example, the PR switch portion 102a, the SCA switch portion 102b, and the SCB switch portion 102c may be included in one integrated circuit, and the SMA switch portion 102d, the SMB switch portion 102e, and the SMC switch portion 102f may be included in another one integrated circuit. Further, for example, the SCA switch portion 102b, the SCB switch portion 102c, the SMA switch portion 102d, the SMB switch portion 102e, and the SMC switch portion 102f may be included in one integrated circuit, and the PR switch portion 102a may be included in another one integrated circuit. At this time, the digital control unit 102g may be included in each of the plurality of integrated circuits or may be included in only one of the plurality of integrated circuits. The plurality of integrated circuits may be manufactured at different process technology nodes.

The integrated circuit 102 is configured by using, for example, CMOS (complementary metal oxide semiconductor), and more specifically, may be manufactured by an SOI (silicon on insulator) process. It is noted that the integrated circuit 102 is not to be limited to CMOS.

Each of the capacitors C11, C210 to C21F, and C220 to C22F is mounted as a chip capacitor. In an exemplary aspect, the chip capacitor can be a surface mount device (SMD) forming a capacitor. However, it is noted that the mounting of the plurality of capacitors is not limited to chip capacitors. For example, some or all of the capacitors may be included in an IPD (integrated passive device) or may be included in the integrated circuit 102 according to alternative exemplary aspects.

The capacitors C210 to C21F included in the switched-capacitor circuit 21 are disposed in a region on the main surface 101a sandwiched between a straight line along the right side of the integrated circuit 102 and a straight line along the right side of the module laminate 101 when viewed in plan view of the module laminate 101. Thus, the capacitors C210 to C21F included in the switched-capacitor circuit 21 are disposed in the vicinity of the SCA switch portion 102b in the integrated circuit 102. In other words, the SCA switch portion 102b is closer to the capacitors C210 to C21F than the PR switch portion 102a, the SCB switch portion 102c, the SMA switch portion 102d, the SMB switch portion 102e, and the SMC switch portion 102f.

The capacitors C220 to C22F included in the switched-capacitor circuit 22 are disposed in a region on the main surface 101a sandwiched between a straight line along the upper side of the integrated circuit 102 and a straight line along the upper side of the module laminate 101 when viewed in plan view of the module laminate 101. Thus, the capacitors C220 to C22F included in the switched-capacitor circuit 22 are disposed in the vicinity of the SCB switch portion 102c in the integrated circuit 102. In other words, the SCB switch portion 102c is closer to the capacitors C220 to C22F than the PR switch portion 102a, the SCA switch portion 102b, the SMA switch portion 102d, the SMB switch portion 102e, and the SMC switch portion 102f.

A plurality of external connection terminals 103 are disposed on the main surface 101b of the module laminate 101. The plurality of external connection terminals 103 include the external connection terminals 41 to 43 shown in FIG. 2, as well as RF terminals, power supply terminals, control terminals, and ground terminals (not shown).

The plurality of external connection terminals 103 are electrically connected to input/output terminals and/or ground terminals on a mother board (not shown) disposed in the z-axis negative direction of the tracker module 100. The plurality of external connection terminals 103 are electrically connected to a plurality of components disposed on the main surface 101a via conductors or the like formed in the module laminate 101.

Copper electrodes may be used as the plurality of external connection terminals 103, but the plurality of external connection terminals 103 are not limited to copper electrodes. For example, solder electrodes may be used as the plurality of external connection terminals 103 in an alternative exemplary aspect.

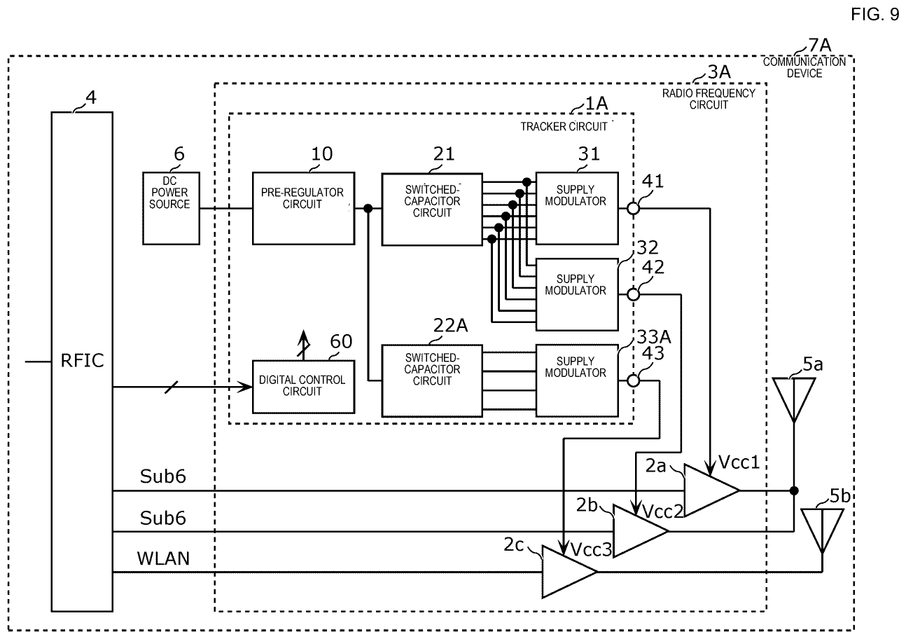

It is noted that the tracker module 100 shown in FIGS. 8 and 9 is an example and is not limited to such an example. For example, some or all of the plurality of components on the main surface 101a of the module laminate 101 may be covered with a resin member (for example, epoxy resin). Thus, reliability such as mechanical strength and moisture resistance of the components on the main surface 101a is improved. Further, the surface of the resin member may be covered with a shield electrode layer formed by, for example, a sputtering method. By connecting the shield electrode layer to the ground, intrusion of the external noise into the components in the tracker module 100 can be suppressed so that interference of the noise generated in the tracker module 100 with other modules or other devices is also suppressed.

### [1.5 Technical Effects]

As described above, the radio frequency circuit 3 according to the present embodiment includes: a power amplifier 2a configured to amplify a first radio frequency signal; a power amplifier 2c configured to amplify a second radio frequency signal; and a tracker circuit 1 configured to supply a voltage to the power amplifiers 2a and 2c. The tracker circuit 1 includes: a pre-regulator circuit 10 configured to convert an input voltage into a regulated voltage; a switched-capacitor circuit 21 configured to generate a first plurality of discrete voltages (V11 to V16) based on the regulated voltage; a switched-capacitor circuit 22 configured to generate a second plurality of discrete voltages (V21 to V26) based on the regulated voltage; a supply modulator 31 configured to selectively output at least one of the first plurality of discrete voltages (V11 to V16) to the power amplifier 2a based on the first radio frequency signal; and a supply modulator 33 configured to selectively output at least one of the second plurality of discrete voltages (V21 to V26) to the power amplifier 2c based on the second radio frequency signal. The first radio frequency signal is a Sub6 signal of a cellular network, and the second radio frequency signal is a WLAN signal.

With such a configuration, the two switched-capacitor circuits 21 and 22 generate the first plurality of discrete voltages (V11 to V16) for the power amplifier 2a that amplifies the Sub6 signal of the cellular network, and the second plurality of discrete voltages (V21 to V26) for the power amplifier 2c that amplifies the WLAN signal. Therefore, a plurality of discrete voltages can be generated that are suitable for amplifying each of the Sub6 signal and the WLAN signal, which may differ in maximum output power, modulation band width, required quality, and/or the like, so that the power efficiency of the power amplifier 2a and/or the power amplifier 2c is improved, and/or the power efficiency of the tracker circuit 1 is improved. Further, since the regulated voltage converted by the pre-regulator circuit 10 is used in both the switched-capacitor circuits 21 and 22, the tracker circuit 1 can be miniaturized. In particular, since the pre-regulator circuit 10 includes the power inductor L11, which has a relatively large size, the effect of the miniaturization of the tracker circuit 1 is greater than that of a tracker circuit in which the switched-capacitor circuits 21 and 22 are each provided with a pre-regulator circuit.

Further, for example, in the radio frequency circuit 3 according to the present embodiment, a highest voltage (V26) among the second plurality of discrete voltages (V21 to V26) may be lower than a highest voltage (V16) among the first plurality of discrete voltages (V11 to V16).

With such a configuration, the highest voltage (V26) among the second plurality of discrete voltages (V21 to V26) for amplifying the WLAN signal is lower than the highest voltage (V16) among the first plurality of discrete voltages (V11 to V16) for amplifying the Sub6 signal of the cellular network. The maximum output power of the WLAN signal using an unlicensed band is lower than the maximum output power of the Sub6 signal of the cellular network using a licensed band. In other words, it is possible to include the high voltage corresponding to the maximum output power of the Sub6 signal in the first plurality of discrete voltages while excluding the high voltage unnecessary for amplifying the WLAN signal from the second plurality of discrete voltages, so that the power efficiency of the tracker circuit 1 and/or the power amplifier 2c is improved.

Further, for example, in the radio frequency circuit 3 according to the present embodiment, an average of level differences between adjacent voltages of the second plurality of discrete voltages (V21 to V26) may be smaller than an average of level differences between adjacent voltages of the first plurality of discrete voltages (V11 to V16).

With such a configuration, when amplifying a WLAN signal having a lower maximum output power, the power supply voltage can be controlled with a finer step width, so that the power efficiency of the power amplifier 2c is improved. Further, distortion of a WLAN signal can bs suppressed in which a higher-order QAM (Quadrature Amplitude Modulation) can be used, thereby contributing to improvement of the communication quality of the WLAN signal and/or improvement of the line speed (data throughput).

Further, for example, in the radio frequency circuit 3 according to the present embodiment, the switched-capacitor circuit 21 may be configured to generate the first plurality of discrete voltages (V11 to V16) by raising and lowering the regulated voltage, and the switched-capacitor circuit 22 may be configured to generate the second plurality of discrete voltages (V21 to V26) by lowering the regulated voltage without raising the regulated voltage.

With such a configuration, in the switched-capacitor circuit 21, the first plurality of discrete voltages including a voltage higher than the regulated voltage can be generated by raising the regulated voltage. On the other hand, in the switched-capacitor circuit 22, the second plurality of discrete voltages not including a voltage higher than the regulated voltage can be generated by lowering the regulated voltage without raising the regulated voltage. Therefore, the highest voltage (V26) among the second plurality of discrete voltages (V21 to V26) for amplifying the WLAN signal can be made lower than the highest voltage (V16) among the first plurality of discrete voltages (V11 to V16) for amplifying the Sub6 signal of the cellular network. As a result, the second plurality of discrete voltages can be optimized for amplifying the WLAN signal, so that the power efficiency of the power amplifier 2c is improved. Further, the regulated voltage of the pre-regulator circuit 10 can be used in both the switched-capacitor circuits 21 and 22, so that the tracker circuit 1 can be miniaturized.

Further, the tracker module 100 according to the present embodiment includes: a module laminate 101; at least one integrated circuit 102 disposed on the module laminate 101; an external connection terminal 103 (41) externally connected to a power amplifier 2a configured to amplify a first radio frequency signal; and an external connection terminal 103 (43) externally connected to a power amplifier 2c configured to amplify a second radio frequency signal. The at least one integrated circuit 102 includes a plurality of switches included in a switched-capacitor circuit 21, a switched-capacitor circuit 22, a supply modulator 31, and a supply modulator 33, the switched-capacitor circuit 21 is configured to generate a first plurality of discrete voltages (V11 to V16) based on a regulated voltage, the switched-capacitor circuit 22 is configured to generate a second plurality of discrete voltages (V21 to V26) based on the regulated voltage, the supply modulator 31 is configured to selectively output at least one of the first plurality of discrete voltages (V11 to V16) to the external connection terminal 103 (41) based on the first radio frequency signal, and the supply modulator 33 is configured to selectively output at least one of the second plurality of discrete voltages (V21 to V26) to the external connection terminal 103 (43) based on the second radio frequency signal. The first radio frequency signal is a Sub6 signal of a cellular network, and the second radio frequency signal is a WLAN signal.

With such a configuration, the first plurality of discrete voltages (V11 to V16) are selectively outputted to the external connection terminal 103 (41) externally connected to the power amplifier 2a that amplifies the Sub6 signal of the cellular network, and the second plurality of discrete voltages (V21 to V26) are selectively outputted to the external connection terminal 103 (43) externally connected to the power amplifier 2c that amplifies the WLAN signal. Therefore, a plurality of discrete voltages can be supplied that are configured for amplifying the Sub6 signal and the WLAN signal, which may differ in maximum output power, modulation band width, required quality, and/or the like, to the power amplifiers 2a and 2c, so that the power efficiency of the power amplifier 2a and/or the power amplifier 2c is improved, and/or the power efficiency of the tracker module 100 is improved. Further, since the regulated voltage converted by the pre-regulator circuit 10 is used in both the switched-capacitor circuits 21 and 22, the tracker module 100 can be miniaturized. In particular, since the pre-regulator circuit 10 includes the power inductor L11, which has a relatively large size, the effect of miniaturization of the tracker module 100 is greater than that of a tracker module in which the switched-capacitor circuits 21 and 22 are each provided with a pre-regulator circuit.

Further, the amplification method according to the present embodiment includes: converting an input voltage into a regulated voltage; generating a first plurality of discrete voltages (V11 to V16) based on the regulated voltage; selectively supplying at least one of the first plurality of discrete voltages (V11 to V16) to a power amplifier 2a based on an envelope signal of a first radio frequency signal; amplifying the first radio frequency signal with the power amplifier 2a; generating a second plurality of discrete voltages (V21 to V26) based on the regulated voltage; selectively supplying at least one of the second plurality of discrete voltages (V21 to V26) to a power amplifier 2c based on an envelope signal of a second radio frequency signal; and amplifying the second radio frequency signal with the power amplifier 2c. The first radio frequency signal is a Sub6 signal of a cellular network, and the second radio frequency signal is a WLAN signal.

Thus, the first plurality of discrete voltages (V11 to V16) for the power amplifier 2a that amplifies the Sub6 signal of the cellular network are generated, and the second plurality of discrete voltages (V21 to V26) for the power amplifier 2c that amplifies the WLAN signal are generated. Therefore, a plurality of discrete voltages are generated that are configured for amplifying each of the Sub6 signal and the WLAN signal, which may differ in maximum output power, modulation band width, required quality, and/or the like, so that the power efficiency of the power amplifier 2a and/or the power amplifier 2c is improved, and/or the power efficiency of the tracker circuit 1 is improved.

### Second Exemplary Embodiment

Next, a second exemplary will be described. The second exemplary embodiment is mainly different from the first exemplary embodiment in that the number of the second plurality of discrete voltages selectively supplied to the power amplifier that amplifies the WLAN signal is smaller than the number of the first plurality of discrete voltages selectively supplied to the power amplifier that amplifies the Sub6 signal of the cellular network. Hereinafter, the present embodiment will be described with reference to the drawings, focusing on points different from the first exemplary embodiment.

### [2.1 Circuit Configuration of Communication Device 7A]

The circuit configuration of a communication device 7A according to the present embodiment will be described with reference to FIG. 9. FIG. 9 is a circuit configuration diagram of the communication device 7A according to the present embodiment.

It is noted that FIG. 9 is an exemplary circuit configuration, and the communication device 7A may be mounted using any of a wide variety of circuit mounting and circuit techniques. Therefore, the description of the communication device 7A provided below is not to be interpreted in a limited manner. The communication device 7A according to the present embodiment includes a radio frequency circuit 3A, an RFIC 4, antennas 5a and 5b, and a DC power source 6, in which the radio frequency circuit 3A includes a tracker circuit 1A and power amplifiers 2a to 2c. It is noted that the radio frequency circuit 3A may omit the power amplifier 2b in an exemplary aspect.

The tracker circuit 1A is connected between the DC power source 6 and the power amplifiers 2a to 2c and can supply power supply voltages (Vcc1 to Vcc3) to the power amplifiers 2a to 2c. The circuit configuration of the tracker circuit 1A will be described later.

It is noted that the circuit configurations of the communication device 7A and the radio frequency circuit 3A shown in FIG. 9 are examples and are not limited to such examples. For example, the communication device 7A may include a baseband signal processing circuit that performs signal processing using a frequency band lower than the radio frequency signal. Further, the radio frequency circuit 3A may include a filter connected between the power amplifier 2a and the antenna 5a, and/or a filter connected between the power amplifier 2b and the antenna 5a. Further, the radio frequency circuit 3A may include a filter connected between the power amplifier 2c and the antenna 5b. Further, the radio frequency circuit 3A may include a switch connected between the power amplifiers 2a to 2c and the antennas 5a and 5b.

### [2.2 Circuit Configuration of Tracker Circuit 1A]

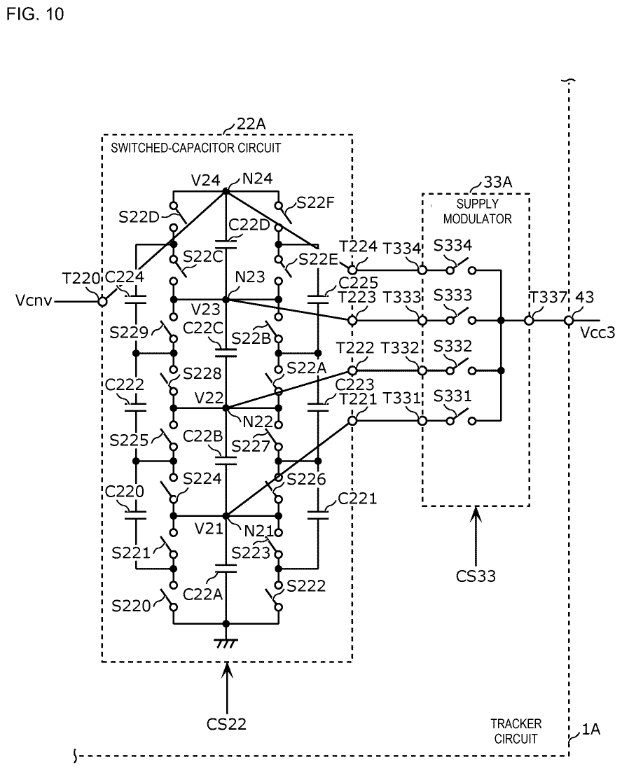

Next, the circuit configuration of the tracker circuit 1A will be described with reference to FIGS. 9 and 10. FIG. 10 is a circuit configuration diagram of a switched-capacitor circuit 22A and a supply modulator 33A according to the present embodiment.

It is noted that FIGS. 9 and 10 are exemplary circuit configurations, and the tracker circuit 1A, the switched-capacitor circuit 22A, and the supply modulator 33A may be mounted using any of a wide variety of circuit mounting and circuit techniques. Therefore, the description of each circuit provided below is not to be interpreted in a limited manner.

Since the mounting of the tracker circuit 1A is the same as that of tracker circuit 1 according to the first exemplary embodiment, the illustration and description of a tracker module according to the present embodiment will be omitted.

The tracker circuit 1A includes a pre-regulator circuit 10, switched-capacitor circuits 21 and 22A, supply modulators 31, 32, and 33A, external connection terminals 41 to 43, and a digital control circuit 60. It is noted that the tracker circuit 1A may omit the pre-regulator circuit 10 and/or the supply modulator 32 and the external connection terminal 42 according to various exemplary aspects.

The switched-capacitor circuit 22A is an example of the second switched-capacitor circuit and is configured to generate a second plurality of discrete voltages based on a regulated voltage supplied from the pre-regulator circuit 10. In the present embodiment, the switched-capacitor circuit 22A is configured to generate the second plurality of discrete voltages by lowering the regulated voltage without raising the regulated voltage. The circuit configuration of switched-capacitor circuit 22A will be described later with reference to FIG. 10.

The supply modulator 33A is an example of the second supply modulator and can selectively output at least one of the second plurality of discrete voltages generated by the switched-capacitor circuit 22A to the power amplifier 2c. In other words, the supply modulator 33A can select at least one voltage from the second plurality of discrete voltages and supply the selected voltage to the power amplifier 2c. The circuit configuration of the supply modulator 33A will be described later with reference to FIG. 10.

It is noted that the circuit configuration of the tracker circuit 1A is an example and is not limited to such an example. For example, the tracker circuit 1A may include a PSN connected between the supply modulator 31 and the external connection terminal 41 and/or a PSN connected between the supply modulator 32 and the external connection terminal 42. Also, the tracker circuit 1A may include a PSN connected between the supply modulator 33A and the external connection terminal 43.

### [2.2.1 Circuit Configuration of Switched-Capacitor Circuit 22A]

Next, the circuit configuration of the switched-capacitor circuit 22A included in the tracker circuit 1A will be described with reference to FIG. 10.

In the switched-capacitor circuit 22A, an input terminal T220 is connected to a node N24 having the highest potential, and the number of stages in a ladder type circuit configuration is smaller than that in the switched-capacitor circuit 22. Thus, the switched-capacitor circuit 22A is configured to generate a second plurality of discrete voltages (V21 to V24) different from and smaller than the first plurality of discrete voltages (V11 to V16) generated by the switched-capacitor circuit 21.

In the present embodiment, the highest voltage (V24) among the second plurality of discrete voltages (V21 to V24) is lower than the highest voltage (V16) among the first plurality of discrete voltages (V11 to V16).

The switched-capacitor circuit 22A has a ladder type circuit configuration. Specifically, the switched-capacitor circuit 22A includes capacitors C220 to C225 and C22A to C22D, switches S220 to S22F, the input terminal T220, and output terminals T221 to T224. Energy and electric charges are inputted from the pre-regulator circuit 10 to a node N24 via the input terminal T220 and are extracted from nodes N21 to N24 to the supply modulator 33A via the output terminals T221 to T224.

The input terminal T220 is a terminal for receiving the regulated voltage from the pre-regulator circuit 10. The input terminal T220 is externally connected to the pre-regulator circuit 10 and internally connected to the node N24.

The output terminal T221 is a terminal for supplying a voltage (V21) of the second plurality of discrete voltages (V21 to V24) to the supply modulator 33A. The output terminal T221 is externally connected to the supply modulator 33A and internally connected to the node N21.

The output terminal T222 is a terminal for supplying a voltage (V22) of the second plurality of discrete voltages (V21 to V24) to the supply modulator 33A. The output terminal T222 is externally connected to the supply modulator 33A and internally connected to the node N22.

The output terminal T223 is a terminal for supplying a voltage (V23) of the second plurality of discrete voltages (V21 to V24) to the supply modulator 33A. The output terminal T223 is externally connected to the supply modulator 33A and internally connected to the node N23.

The output terminal T224 is a terminal for supplying a voltage (V24) of the second plurality of discrete voltages (V21 to V24) to the supply modulator 33A. The output terminal T224 is externally connected to the supply modulator 33A and internally connected to the node N24.

The capacitors C220 to C225 can be flying capacitors (sometimes referred to as transfer capacitors) and can be configured to lower the regulated voltage (V24) supplied from the pre-regulator circuit 10. Specifically, the capacitors C220 to C225 transfer electric charges between the capacitors C220 to C225 and the nodes N21 to N24 and the ground so that V21 to V24 satisfying (V24−V23):(V23−V22):(V22−V21):(V21−VG)=1:1:1:1 and V24>V23>V22>V21>VG are maintained at the four nodes N21 to N24.

One of the two electrodes of the capacitor C220 is connected to one end of the switch S220 and one end of the switch S221. The other of the two electrodes of the capacitor C220 is connected to one end of the switch S224 and one end of the switch S225.

One of the two electrodes of the capacitor C221 is connected to one end of the switch S222 and one end of the switch S223. The other of the two electrodes of the capacitor C221 is connected to one end of the switch S226 and one end of the switch S227.

One of the two electrodes of the capacitor C222 is connected to one end of the switch S224 and one end of the switch S225. The other of the two electrodes of the capacitor C222 is connected to one end of the switch S228 and one end of the switch S229.

One of the two electrodes of the capacitor C223 is connected to one end of the switch S226 and one end of the switch S227. The other of the two electrodes of the capacitor C223 is connected to one end of the switch S22A and one end of the switch S22B.

One of the two electrodes of the capacitor C224 is connected to one end of the switch S228 and one end of the switch S229. The other of the two electrodes of the capacitor C224 is connected to one end of the switch S22C and one end of the switch S22D.

One of the two electrodes of the capacitor C225 is connected to one end of the switch S22A and one end of the switch S22B. The other of the two electrodes of the capacitor C225 is connected to one end of the switch S22E and one end of the switch S22F.

The capacitors C22A to C22D can be smoothing capacitors that are configured to hold and smooth the voltages (V21 to V24) at the nodes N21 to N24.

The capacitor C22A is connected between the node N21 and the ground. Specifically, one of the two electrodes of the capacitor C22A is connected to the node N21. On the other hand, the other of the two electrodes of the capacitor C22A is connected to the ground.

The capacitor C22B is connected between the nodes N21 and N22. Specifically, one of the two electrodes of the capacitor C22B is connected to the node N22. On the other hand, the other of the two electrodes of the capacitor C22B is connected to the node N21.

The capacitor C22C is connected between the nodes N22 and N23. Specifically, one of the two electrodes of the capacitor C22C is connected to the node N23. On the other hand, the other of the two electrodes of the capacitor C22C is connected to the node N22.

The capacitor C22D is connected between the nodes N23 and N24. Specifically, one of the two electrodes of the capacitor C22D is connected to the node N24. On the other hand, the other of the two electrodes of the capacitor C22D is connected to the node N23.

The switch S220 is connected between the capacitor C220 and the ground. Specifically, one end of the switch S220 is connected to one of the two electrodes of the capacitor C220. On the other hand, the other end of the switch S220 is connected to the ground.

The switch S221 is connected between the capacitor C220 and the node N21. Specifically, one end of the switch S221 is connected to one of the two electrodes of the capacitor C220. On the other hand, the other end of the switch S221 is connected to the node N21.

The switch S222 is connected between the capacitor C221 and the ground. Specifically, one end of the switch S222 is connected to one of the two electrodes of the capacitor C221. On the other hand, the other end of the switch S222 is connected to the ground.

The switch S223 is connected between the capacitor C221 and the node N21. Specifically, one end of the switch S223 is connected to one of the two electrodes of the capacitor C221. On the other hand, the other end of the switch S223 is connected to the node N21.

The switch S224 is connected between the capacitors C220 and C222 and the node N21. Specifically, one end of the switch S224 is connected to the other of the two electrodes of the capacitor C220 and one of the two electrodes of the capacitor C222. On the other hand, the other end of the switch S224 is connected to the node N21.

The switch S225 is connected between the capacitors C220 and C222 and the node N22. Specifically, one end of the switch S225 is connected to the other of the two electrodes of the capacitor C220 and one of the two electrodes of the capacitor C222. On the other hand, the other end of the switch S225 is connected to the node N22.

The switch S226 is connected between the capacitors C221 and C223 and the node N21. Specifically, one end of the switch S226 is connected to the other of the two electrodes of the capacitor C221 and one of the two electrodes of the capacitor C223. On the other hand, the other end of the switch S226 is connected to the node N21.

The switch S227 is connected between the capacitors C221 and C223 and the node N22. Specifically, one end of the switch S227 is connected to the other of the two electrodes of the capacitor C221 and one of the two electrodes of the capacitor C223. On the other hand, the other end of the switch S227 is connected to the node N22.

The switch S228 is connected between the capacitors C222 and C224 and the node N22. Specifically, one end of the switch S228 is connected to the other of the two electrodes of the capacitor C222 and one of the two electrodes of the capacitor C224. On the other hand, the other end of the switch S228 is connected to the node N22.

The switch S229 is connected between the capacitors C222 and C224 and the node N23. Specifically, one end of the switch S229 is connected to the other of the two electrodes of the capacitor C222 and one of the two electrodes of the capacitor C224. On the other hand, the other end of the switch S229 is connected to the node N23.

The switch S22A is connected between the capacitors C223 and C225 and the node N22. Specifically, one end of the switch S22A is connected to the other of the two electrodes of the capacitor C223 and one of the two electrodes of the capacitor C225. On the other hand, the other end of the switch S22A is connected to the node N22.

The switch S22B is connected between the capacitors C223 and C225 and the node N23. Specifically, one end of the switch S22B is connected to the other of the two electrodes of the capacitor C223 and one of the two electrodes of the capacitor C225. On the other hand, the other end of the switch S22B is connected to the node N23.

The switch S22C is connected between the capacitor C224 and the node N23. Specifically, one end of the switch S22C is connected to the other of the two electrodes of the capacitor C224. On the other hand, the other end of the switch S22C is connected to the node N23.

The switch S22D is connected between the capacitor C224 and the node N24. Specifically, one end of the switch S22D is connected to the other of the two electrodes of the capacitor C224. On the other hand, the other end of the switch S22D is connected to the node N24.

The switch S22E is connected between the capacitor C225 and the node N23. Specifically, one end of the switch S22E is connected to the other of the two electrodes of the capacitor C225. On the other hand, the other end of the switch S22E is connected to the node N23.

The switch S22F is connected between the capacitor C225 and the node N24. Specifically, one end of the switch S22F is connected to the other of the two electrodes of the capacitor C225. On the other hand, the other end of the switch S22F is connected to the node N24.

A first set of switches including the switches S220, S223, S224, S227, S228, S22B, S22C and S22F, and a second set of switches including the switches S221, S222, S225, S226, S229, S22A, S22D and S22E are mutually reversely switched ON and OFF based on a control signal CS22 from the digital control circuit 60.

Specifically, in a first phase, the first set of switches are closed, and the second set of switches are opened. Thus, one of the two electrodes of the capacitor C220 is connected to the ground. The other of the two electrodes of the capacitor C220, one of the two electrodes of the capacitor C221, and one of the two electrodes of the capacitor C222 are connected to the node N21. The other of the two electrodes of the capacitor C221, the other of the two electrodes of the capacitor C222, one of the two electrodes of the capacitor C223, and one of the two electrodes of the capacitor C224 are connected to the node N22. The other of the two electrodes of the capacitor C223, the other of the two electrodes of the capacitor C224, and one of the two electrodes of the capacitor C225 are connected to the node N23. The other of the two electrodes of the capacitor C225 is connected to the node N24.

Conversely, in a second phase, the first set of switches are opened, and the second set of switches are closed. Thus, one of the two electrodes of the capacitor C221 is connected to the ground. One of the two electrodes of the capacitor C220, the other of the two electrodes of the capacitor C221, and one of the two electrodes of the capacitor C223 are connected to the node N21. The other of the two electrodes of the capacitor C220, one of the two electrodes of the capacitor C222, the other of the two electrodes of the capacitor C223, and one of the two electrodes of the capacitor C225 are connected to the node N22. The other of the two electrodes of the capacitor C222, one of the two electrodes of the capacitor C224, and the other of the two electrodes of the capacitor C225 are connected to the node N23. The other of the two electrodes of the capacitor C224 is connected to the node N24.

By repeating the first phase and the second phase, the capacitors C220 to C225 can be charged and discharged complementarily. For example, charging from the capacitors C220, C222, and C224 to the capacitors C22A to C22D is performed in one of the first phase and the second phase, and charging from the capacitors C221, C223, and C225 to the capacitors C22A to C22D is performed in the other of the first phase and the second phase. In other words, since the capacitors C22A to C22D are constantly charged from any one of the capacitors C220 to C225, even when a current flows at a high speed from any one of the nodes N21 to N24 to the supply modulator 33A, electric charges are replenished at a high speed to any one of the nodes N21 to N24, so that the potential fluctuation of the nodes N21 to N24 can be suppressed.

By operating in such a manner, the switched-capacitor circuit 22A can maintain substantially equal voltages at both ends of each of the capacitors C22A to C22D. Specifically, V21 to V24 satisfying (V24−V23):(V23−V22):(V22−V21):(V21−VG)=1:1:1:1 are maintained at the four nodes N21 to N24 labeled V21 to V24. For example, when the regulated voltage supplied from the pre-regulator circuit 10 is 5 V, the switched-capacitor circuit 22A can be configured to generate (1.25 V, 2.5 V, 3.75 V, 5 V) as the second plurality of discrete voltages (V21 to V24).

It is noted that (V24−V23):(V23−V22):(V22−V21):(V21−VG) are not limited to 1:1:1:1 and can be designed to be any ratio (for example, 1:2:3:4, 4:3:2:1, or the like) according to various exemplary aspects.

### [2.2.2 Circuit Configuration of Supply Modulator 33A]

Next, the circuit configuration of the supply modulator 33A included in the tracker circuit 1A will be described with reference to FIG. 10.

The supply modulator 33A includes input terminals T331 to T334, switches S331 to S334, and an output terminal T337. The circuit configuration of the supply modulator 33A is the same as that of the supply modulator 31 except that the input terminals T331 to T334 are externally connected to the switched-capacitor circuit 22A and the output terminal T337 is externally connected to the power amplifier 2c. The details of the circuit configuration of the supply modulator 33A will be described below.

The input terminals T331 to T334 are terminals for receiving the second plurality of discrete voltages (V21 to V24) generated by the switched-capacitor circuit 22A. The input terminals T331 to T334 are externally connected to the output terminals T221 to T224 of the switched-capacitor circuit 22A, respectively, and internally connected to the switches S331 to S334, respectively.

The output terminal T337 is a terminal for supplying the power supply voltage (Vcc3) to the power amplifier 2c. The output terminal T337 is externally connected to the power amplifier 2c and internally connected to the switches S331 to S334.

The switch S331 is connected between the input terminal T331 and the output terminal T337. In such a connection configuration, the switch S331 can switch the connection and disconnection between the input terminal T331 and the output terminal T337 by being switched ON and OFF by a control signal CS33 from the digital control circuit 60.

The switch S332 is connected between the input terminal T332 and the output terminal T337. In such a connection configuration, the switch S332 can switch the connection and disconnection between the input terminal T332 and the output terminal T337 by being switched ON and OFF by the control signal CS33 from the digital control circuit 60.

The switch S333 is connected between the input terminal T333 and the output terminal T337. In such a connection configuration, the switch S333 can switch the connection and disconnection between the input terminal T333 and the output terminal T337 by being switched ON and OFF by the control signal CS33 from the digital control circuit 60.

The switch S334 is connected between the input terminal T334 and the output terminal T337. In such a connection configuration, the switch S334 can switch the connection and disconnection between the input terminal T334 and the output terminal T337 by being switched ON and OFF by the control signal CS33 from the digital control circuit 60.

In the present embodiment, the switches S331 to S334 are controlled so as to be turned on exclusively. In other words, the switches S331 to S334 are controlled so that only one of the switches S331 to S334 is closed and the remainder of the switches S331 to S334 are all opened. Thus, the supply modulator 33A can supply one voltage selected from the second plurality of discrete voltages (V21 to V24) to the power amplifier 2c as the power supply voltage (Vcc3).

It is noted that the configuration of the supply modulator 33A shown in FIG. 10 is an example and is not limited to such an example. In particular, the switches S331 to S334 may have any configuration and may be controlled in any manner as long as at least one of the four input terminals T331 to T334 can be selectively connected to the output terminal T337. For example, two of the switches S331 to S334 may be closed and the remainder of the switches S331 to S334 may be opened.

### [2.3 Technical Effects]

As described above, the radio frequency circuit 3A according to the present embodiment includes: a power amplifier 2a configured to amplify a first radio frequency signal; a power amplifier 2c configured to amplify a second radio frequency signal; and a tracker circuit 1A configured to supply a voltage to the power amplifiers 2a and 2c. The tracker circuit 1A includes: a pre-regulator circuit 10 configured to convert an input voltage into a regulated voltage; a switched-capacitor circuit 21 configured to generate a first plurality of discrete voltages (V11 to V16) based on the regulated voltage; a switched-capacitor circuit 22A configured to generate a second plurality of discrete voltages (V21 to V24) based on the regulated voltage; a supply modulator 31 configured to selectively output at least one of the first plurality of discrete voltages (V11 to V16) to the power amplifier 2a based on the first radio frequency signal; and a supply modulator 33A configured to selectively output at least one of the second plurality of discrete voltages (V21 to V24) to the power amplifier 2c based on the second radio frequency signal. The first radio frequency signal is a Sub6 signal of a cellular network, and the second radio frequency signal is a WLAN signal.

With such a configuration, the two switched-capacitor circuits 21 and 22A generate the first plurality of discrete voltages (V11 to V16) for the power amplifier 2a that amplifies the Sub6 signal of the cellular network, and the second plurality of discrete voltages (V21 to V24) for the power amplifier 2c that amplifies the WLAN signal. Therefore, a plurality of discrete voltages can be generated that are configured for amplifying each of the Sub6 signal and the WLAN signal, which may differ in maximum output power, modulation band width, required quality, and/or the like, so that the power efficiency of the power amplifier 2a and/or the power amplifier 2c is improved, and/or the power efficiency of the tracker circuit 1A is improved. Further, since the regulated voltage converted by the pre-regulator circuit 10 is used in both the switched-capacitor circuits 21 and 22A, the tracker circuit 1A can be miniaturized. In particular, since the pre-regulator circuit 10 includes the power inductor L11, which has a relatively large size, the effect of miniaturization of the tracker circuit 1A is greater than that of a tracker circuit in which the switched-capacitor circuits 21 and 22A are each provided with a pre-regulator circuit.

Further, for example, in the radio frequency circuit 3A according to the present embodiment, a highest voltage (V24) among the second plurality of discrete voltages (V21 to V24) may be lower than a highest voltage (V16) among the first plurality of discrete voltages (V11 to V16).

With such a configuration, the highest voltage (V24) among the second plurality of discrete voltages (V21 to V24) for amplifying the WLAN signal is lower than the highest voltage (V16) among the first plurality of discrete voltages (V11 to V16) for amplifying the Sub6 signal of the cellular network. The maximum output power of the WLAN signal using an unlicensed band is lower than the maximum output power of the Sub6 signal of the cellular network using a licensed band. In other words, it is possible to include the high voltage corresponding to the maximum output power of the Sub6 signal in the first plurality of discrete voltages while excluding the high voltage unnecessary for amplifying the WLAN signal from the second plurality of discrete voltages, so that the power efficiency of the power amplifier 2c and/or the tracker circuit 1A is improved.

Further, for example, in the radio frequency circuit 3A according to the present embodiment, the switched-capacitor circuit 21 may be configured to generate the first plurality of discrete voltages (V11 to V16) by raising and lowering the regulated voltage, and the switched-capacitor circuit 22A may be configured to generate the second plurality of discrete voltages (V21 to V24) by lowering the regulated voltage without raising the regulated voltage.

With such a configuration, in the switched-capacitor circuit 21, the first plurality of discrete voltages including a voltage higher than the regulated voltage can be generated by raising the regulated voltage. On the other hand, in the switched-capacitor circuit 22A, the second plurality of discrete voltages not including a voltage higher than the regulated voltage can be generated by lowering the regulated voltage without raising the regulated voltage. Therefore, the highest voltage (V24) among the second plurality of discrete voltages (V21 to V24) for amplifying the WLAN signal can be made lower than the highest voltage (V16) among the first plurality of discrete voltages (V11 to V16) for amplifying the Sub6 signal of the cellular network. As a result, the second plurality of discrete voltages can be optimized for amplifying the WLAN signal, so that the power efficiency of the power amplifier 2c is improved. Further, the regulated voltage of the pre-regulator circuit 10 can be used in both the switched-capacitor circuits 21 and 22A, so that the tracker circuit 1A can be miniaturized.

Further, for example, in the radio frequency circuit 3A according to the present embodiment, the number of the second plurality of discrete voltages (V21 to V24) may be smaller than the number of the first plurality of discrete voltages (V11 to V16).

With such a configuration, the number of the second plurality of discrete voltages (V21 to V24) can be reduced, so that the power efficiency of the tracker circuit 1A is improved.

### Third Exemplary Embodiment

Next, a third exemplary embodiment will be described. The third exemplary embodiment is mainly different from the first exemplary embodiment in that a millimeter-wave signal of a cellular network is used instead of the WLAN signal. Hereinafter, the present embodiment will be described with reference to the drawings, focusing on points different from the first exemplary embodiment.

### [3.1 Circuit Configuration of Communication Device 7B]

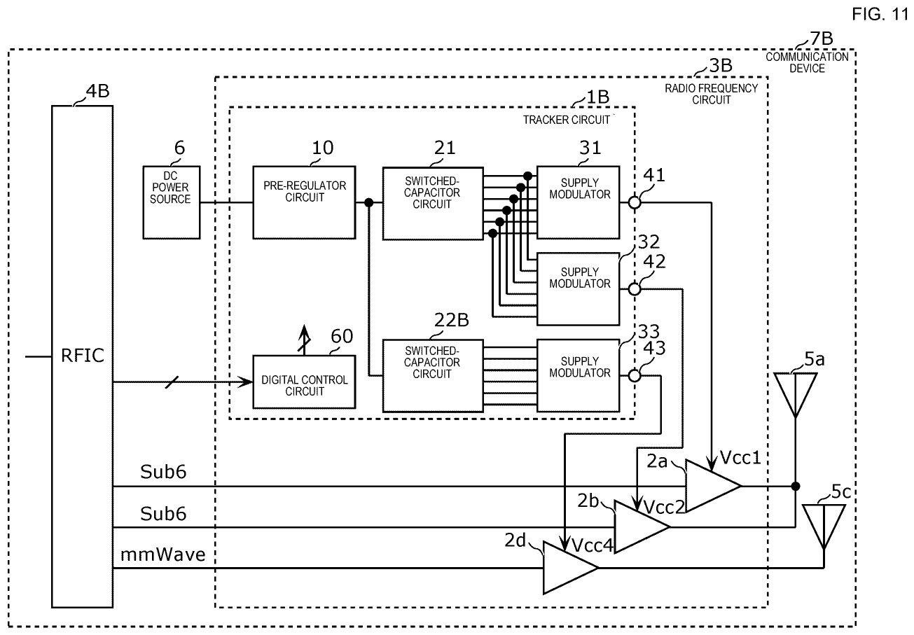

A circuit configuration of a communication device 7B according to the present embodiment will be described with reference to FIG. 11. FIG. 11 is a circuit configuration diagram of the communication device 7B according to the present embodiment.

It is noted that FIG. 11 is an exemplary circuit configuration, and the communication device 7B may be mounted using any of a wide variety of circuit mounting and circuit techniques. Therefore, the description of the communication device 7B provided below is not to be interpreted in a limited manner. The communication device 7B according to the present embodiment includes a radio frequency circuit 3B, an RFIC 4B, antennas 5a and 5c, and a DC power source 6, in which the radio frequency circuit 3B includes a tracker circuit 1B and power amplifiers 2a, 2b, and 2d. It is noted that the radio frequency circuit 3B may omit the power amplifier 2b in an exemplary aspect.

The tracker circuit 1B is connected between the DC power source 6 and the power amplifiers 2a, 2b, and 2d and can supply the power supply voltages (Vcc1, Vcc2, and Vcc4) to the power amplifiers 2a, 2b, and 2d. The circuit configuration of the tracker circuit 1B will be described later.

The power amplifier 2d is an example of the second power amplifier and can amplify a millimeter-wave signal of a cellular network. The power amplifier 2d is connected between the RFIC 4B and the antenna 5c and is further connected to the tracker circuit 1B. Note that the power amplifier 2d may amplify a radio frequency signal other than the millimeter-wave signal of the cellular network.

The millimeter-wave signal of the cellular network is an example of the second radio frequency signal and is a signal of a frequency band of 30 to 300 GHz used in the cellular network.

The RFIC 4B is an example of the signal processing circuit and can supply the Sub6 signal of the cellular network and the millimeter-wave signal of the cellular network to the power amplifiers 2a, 2b, and 2d. Note that the RFIC 4B may be divided into an RFIC for the Sub6 signal of the cellular network and an RFIC for the millimeter-wave signal of the cellular network.

The antenna 5c can transmit the millimeter-wave signal amplified by the power amplifier 2d to the outside.

It is noted that the circuit configurations of the communication device 7B and the radio frequency circuit 3B shown in FIG. 11 are examples and are not limited to such examples. For example, the communication device 7B may include a baseband signal processing circuit that performs signal processing using a frequency band lower than the radio frequency signal. Further, the radio frequency circuit 3B may include a filter connected between the power amplifier 2a and the antenna 5a, and/or a filter connected between the power amplifier 2b and the antenna 5a. Further, the radio frequency circuit 3B may include a filter connected between the power amplifier 2d and the antenna 5c. Further, the radio frequency circuit 3B may include a switch connected between the power amplifiers 2a, 2b, and 2d and the antennas 5a and 5c.

### [3.2 Circuit Configuration of Tracker Circuit 1B]

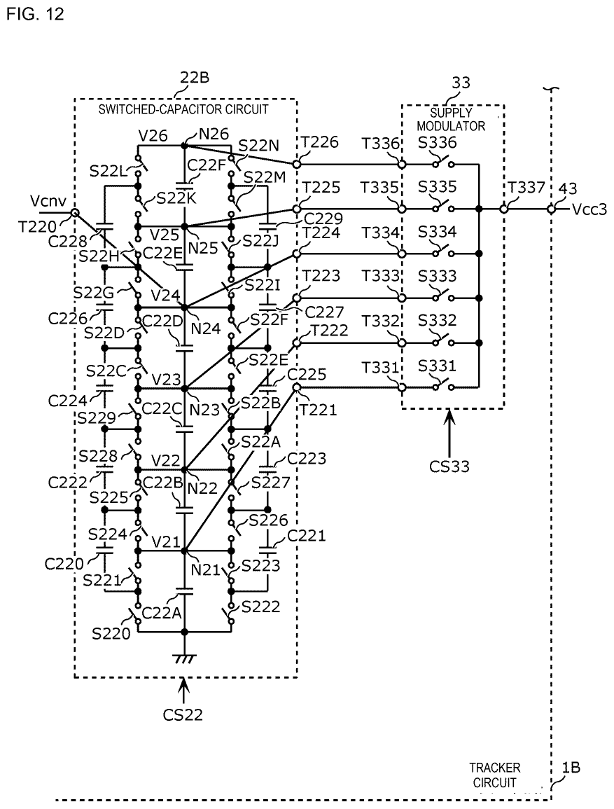

Next, the circuit configuration of the tracker circuit 1B will be described with reference to FIGS. 11 and 12. FIG. 12 is a circuit configuration diagram of a switched-capacitor circuit 22B and a supply modulator 33 according to the present embodiment.

It is noted that FIGS. 11 and 12 are exemplary circuit configurations, and the tracker circuit 1B, the switched-capacitor circuit 22B, and the supply modulator 33 may be mounted using any of a wide variety of circuit mounting and circuit techniques. Therefore, the description of each circuit provided below is not to be interpreted in a limited manner.

Since the mounting of the tracker circuit 1B is the same as that of the tracker circuit 1 according to the first exemplary embodiment, the illustration and description of the tracker module according to the present embodiment will be omitted.

The tracker circuit 1B includes a pre-regulator circuit 10, switched-capacitor circuits 21 and 22B, supply modulators 31 to 33, external connection terminals 41 to 43, and a digital control circuit 60. It is noted that the tracker circuit 1B may omit the pre-regulator circuit 10 and/or the supply modulator 32 and the external connection terminal 42 according to various exemplary aspects.

The switched-capacitor circuit 22B is an example of the second switched-capacitor circuit and is configured to generate a second plurality of discrete voltages based on a regulated voltage supplied from the pre-regulator circuit 10. In the present embodiment, the switched-capacitor circuit 22B is configured to generate the second plurality of discrete voltages by raising and lowering the regulated voltage. The circuit configuration of the switched-capacitor circuit 22B will be described later with reference to FIG. 12.

It is noted that the circuit configuration of the tracker circuit 1B is an example and is not limited to such an example. For example, the tracker circuit 1B may include a PSN connected between the supply modulator 31 and the external connection terminal 41 and/or a PSN connected between the supply modulator 32 and the external connection terminal 42. Also, the tracker circuit 1B may include a PSN connected between the supply modulator 33 and the external connection terminal 43.

### [3.2.1 Circuit Configuration of Switched-Capacitor Circuit 22B]

Next, the circuit configuration of the switched-capacitor circuit 22B included in the tracker circuit 1B will be described with reference to FIG. 12.

The switched-capacitor circuit 22B differs from the switched-capacitor circuits 21 and 22 in that the input terminal T220 is internally connected to a node N24 instead of node N25 or N26. Thus, the switched-capacitor circuit 22B is configured to generate a second plurality of discrete voltages (V21 to V26) different from a first plurality of discrete voltages (V11 to V16) generated by the switched-capacitor circuit 21.

In the present embodiment, the highest voltage (V26) among the second plurality of discrete voltages (V21 to V26) is higher than the highest voltage (V16) among the first plurality of discrete voltages (V11 to V16). Further, the average ({(V26−V25)+(V25−V24)+(V24−V23)+(V23−V22)+(V22−V21)}/5) of the level differences between adjacent voltages of the second plurality of discrete voltages (V21 to V26) is larger than the average ({(V16−V15)+(V15−V14)+(V14−V13)+(V13−V12)+(V12−V11)}/5) of the level differences between adjacent voltages of the first plurality of discrete voltages (V11 to V16).

For example, when the regulated voltage supplied from the pre-regulator circuit 10 is 5 V, the switched-capacitor circuit 22B can be configured to generate (1.25 V, 2.5 V, 3.75 V, 5 V, 6.25 V, 7.5 V) as the second plurality of discrete voltages (V21 to V26).

Since the circuit configuration of the switched-capacitor circuit 22B is substantially the same as that of the switched-capacitor circuit 22, the detailed description thereof will be omitted.

### [3.3 Technical Effects]

As described above, the radio frequency circuit 3B according to the present embodiment includes: a power amplifier 2a configured to amplify a first radio frequency signal; a power amplifier 2d configured to amplify a second radio frequency signal; and a tracker circuit 1B configured to supply a voltage to the power amplifiers 2a and 2d. The tracker circuit 1B includes: a pre-regulator circuit 10 configured to convert an input voltage into a regulated voltage; a switched-capacitor circuit 21 configured to generate a first plurality of discrete voltages (V11 to V16) based on the regulated voltage; a switched-capacitor circuit 22B configured to generate a second plurality of discrete voltages (V21 to V26) based on the regulated voltage; a supply modulator 31 configured to selectively output at least one of the first plurality of discrete voltages (V11 to V16) to the power amplifier 2a based on the first radio frequency signal; and a supply modulator 33 configured to selectively output at least one of the second plurality of discrete voltages (V21 to V26) to the power amplifier 2d based on the second radio frequency signal. The first radio frequency signal is a Sub6 signal of a cellular network, and the second radio frequency signal is a millimeter-wave signal of the cellular network.

With such a configuration, the two switched-capacitor circuits 21 and 22B generate the first plurality of discrete voltages (V11 to V16) for the power amplifier 2a that amplifies the Sub6 signal of the cellular network, and the second plurality of discrete voltages (V21 to V26) for the power amplifier 2d that amplifies the millimeter-wave signal of the cellular network. Therefore, a plurality of discrete voltages can be generated that are configured for amplifying each of the Sub6 signal and the millimeter-wave signal, which may differ in maximum output power, modulation band width, required quality, and/or the like, so that the power efficiency of the power amplifier 2a and/or the power amplifier 2d is improved, and/or the power efficiency of the tracker circuit 1B is improved. Further, since the regulated voltage converted by the pre-regulator circuit 10 is used in both the switched-capacitor circuits 21 and 22B, the tracker circuit 1B can be miniaturized. In particular, since the pre-regulator circuit 10 includes the power inductor L11, which has a relatively large size, the effect of miniaturization of the tracker circuit 1B is greater than that of a tracker circuit in which the switched-capacitor circuits 21 and 22B are each provided with a pre-regulator circuit.

Further, for example, in the radio frequency circuit 3B according to the present embodiment, a highest voltage (V26) among the second plurality of discrete voltages (V21 to V26) may be higher than a highest voltage (V16) among the first plurality of discrete voltages (V11 to V16).

With such a configuration, the highest voltage (V26) among the second plurality of discrete voltages (V21 to V26) for amplifying the millimeter-wave signal of the cellular network is higher than the highest voltage (V16) among the first plurality of discrete voltages (V11 to V16) for amplifying the Sub6 signal of the cellular network. Since the transmission loss of the millimeter-wave signal is larger than that of the Sub6 signal, the maximum output power required for the power amplifier 2d is also higher. In other words, it is possible to include the high voltage corresponding to the maximum output power of the millimeter-wave signal in the second plurality of discrete voltages while excluding the high voltage unnecessary for amplifying the Sub6 signal from the first plurality of discrete voltages, so that the power efficiency of the power amplifier 2a and/or the tracker circuit 1B is improved.

Further, for example, in the radio frequency circuit 3B according to the present embodiment, an average of level differences between adjacent voltages of the second plurality of discrete voltages (V21 to V26) may be larger than an average of level differences between adjacent voltages of the first plurality of discrete voltages (V11 to V16).

With such a configuration, it is possible to suppress the increase of the number of the second plurality of discrete voltages, so that the power efficiency of the tracker circuit 1B is improved.

Further, the tracker module 100 according to the present embodiment includes: a module laminate 101; at least one integrated circuit 102 disposed on the module laminate 101; an external connection terminal 103 (41) externally connected to a power amplifier 2a configured to amplify a first radio frequency signal; and an external connection terminal 103 (43) externally connected to a power amplifier 2d configured to amplify a second radio frequency signal. The at least one integrated circuit 102 includes a plurality of switches included in a switched-capacitor circuit 21, a switched-capacitor circuit 22B, a supply modulator 31, and a supply modulator 33, the switched-capacitor circuit 21 is configured to generate a first plurality of discrete voltages (V11 to V16) based on a regulated voltage, the switched-capacitor circuit 22B is configured to generate the second plurality of discrete voltages (V21 to V26) based on the regulated voltage, the supply modulator 31 is configured to selectively output at least one of the first plurality of discrete voltages (V11 to V16) to the external connection terminal 103 (41) based on the first radio frequency signal, and the supply modulator 33 is configured to selectively output at least one of the second plurality of discrete voltages (V21 to V26) to the external connection terminal 103 (43) based on the second radio frequency signal. The first radio frequency signal is a Sub6 signal of a cellular network, and the second radio frequency signal is a millimeter-wave signal of the cellular network.

With such a configuration, the first plurality of discrete voltages (V11 to V16) are selectively outputted to the external connection terminal 103 (41) externally connected to the power amplifier 2a that amplifies the Sub6 signal of the cellular network, and the second plurality of discrete voltages (V21 to V26) are selectively outputted to the external connection terminal 103 (43) externally connected to the power amplifier 2d that amplifies the millimeter-wave signal of the cellular network. Therefore, a plurality of discrete voltages can be supplied that are configured for amplifying the Sub6 signal and the millimeter-wave signal, which may differ in maximum output power, modulation band width, required quality, and/or the like, to the power amplifier 2a and the power amplifier 2d, so that the power efficiency of the power amplifier 2a and/or the power amplifier 2d is improved, and/or the power efficiency of the tracker module 100 is improved. Further, since the regulated voltage converted by the pre-regulator circuit 10 is used in both the switched-capacitor circuits 21 and 22B, the tracker module 100 can be miniaturized. In particular, since the pre-regulator circuit 10 includes the power inductor L11, which has a relatively large size, the effect of miniaturization of the tracker module 100 is greater than that of a tracker module in which the switched-capacitor circuits 21 and 22B are each provided with a pre-regulator circuit.

Further, the amplification method according to the present embodiment includes: converting an input voltage into a regulated voltage; generating a first plurality of discrete voltages (V11 to V16) based on the regulated voltage; selectively supplying at least one of the first plurality of discrete voltages (V11 to V16) to a power amplifier 2a based on an envelope signal of a first radio frequency signal; amplifying the first radio frequency signal with the power amplifier 2a; generating a second plurality of discrete voltages (V21 to V26) based on the regulated voltage; selectively supplying at least one of the second plurality of discrete voltages (V21 to V26) to the power amplifier 2d based on an envelope signal of a second radio frequency signal; and amplifying the second radio frequency signal with the power amplifier 2d. The first radio frequency signal is a Sub6 signal of a cellular network, and the second radio frequency signal is the millimeter-wave signal of the cellular network.

Thus, the first plurality of discrete voltages (V11 to V16) for the power amplifier 2a that amplifies the Sub6 signal of the cellular network are generated, and the second plurality of discrete voltages (V21 to V26) for the power amplifier 2d that amplifies the millimeter-wave signal of the cellular network are generated. Therefore, a plurality of discrete voltages can be generated that are configured for amplifying each of the Sub6 signal and the millimeter-wave signal, which may differ in maximum output power, modulation band width, required quality, and/or the like, so that the power efficiency of the power amplifier 2a and/or the power amplifier 2d is improved, and/or the power efficiency of the tracker circuit 1B is improved.

### Additional Exemplary Embodiments

The radio frequency circuit, the tracker module and the amplification method according to the exemplary aspects of the present disclosure have been described above with reference to the embodiments. However, the radio frequency circuit, the tracker module and the amplification method described herein are not limited to the embodiments described above. The exemplary aspects of the present disclosure also include other embodiments realized by combining any of the components in the embodiments described above, variations obtained by applying various variations conceived by those skilled in the art to the embodiments described above without departing from the spirit of the present disclosure, and various devices incorporating the radio frequency circuit, the tracker module described above.

For example, other circuit elements, wiring lines and/or the like may be inserted between the paths connecting each circuit element and signal path disclosed in the drawings in the circuit configuration of various circuits according to the embodiments described above. For example, a filter and/or an impedance matching circuit may be inserted between the power amplifier 2a and the antenna 5a.

Further, for example, the number of the plurality of discrete voltages generated by the switched-capacitor circuit in each of the above embodiments is an example and is not limited to the number shown in each of the above embodiments. For example, in each of the above embodiments, the switched-capacitor circuit 21 may generate five or less discrete voltages and may generate seven or more discrete voltages.

The exemplary aspects of the present disclosure, as a radio frequency circuit that amplifies a radio frequency signal, can be widely used in communication devices such as mobile phones.

### REFERENCE SIGNS LIST

1, 1A, 1B tracker circuit
2a, 2b, 2c, 2d power amplifier
3, 3A, 3B radio frequency circuit
4, 4B RFIC
5a, 5b, 5c antenna
6 DC power source
7, 7A, 7B communication device
10 pre-regulator circuit
21, 22, 22A, 22B switched-capacitor circuit
31, 32, 33, 33A supply modulator
41, 42, 43, 103 external connection terminal
60 digital control circuit
100 tracker module
101 module laminate
101a, 101b main surface
102 integrated circuit
102a PR switch portion
102b SCA switch portion
102c SCB switch portion
102d SMA switch portion
102e SMB switch portion
102f SMC switch portion
102g digital control unit

1. A radio frequency circuit comprising:
a first power amplifier configured to amplify a first radio frequency signal;
a second power amplifier configured to amplify a second radio frequency signal; and
a tracker circuit configured to supply a voltage to the first power amplifier and the second power amplifier, the tracker circuit including:
a converter circuit configured to convert an input voltage into a regulated voltage;
a first switched-capacitor circuit configured to generate a first plurality of discrete voltages based on the regulated voltage;
a second switched-capacitor circuit configured to generate a second plurality of discrete voltages based on the regulated voltage;
a first supply modulator configured to selectively output at least one voltage of the first plurality of discrete voltages to the first power amplifier based on the first radio frequency signal; and
a second supply modulator configured to selectively output at least one voltage of the second plurality of discrete voltages to the second power amplifier based on the second radio frequency signal,
wherein the first radio frequency signal is a different signal than the second radio frequency signal.

2. The radio frequency circuit according to claim 1, wherein:
the first radio frequency signal is a Sub6 signal of a cellular network, and
the second radio frequency signal is one of a wireless local area network signal or a millimeter-wave signal of the cellular network.

3. The radio frequency circuit according to claim 2, wherein the second radio frequency signal is the wireless local area network signal.

4. The radio frequency circuit according to claim 3, wherein a highest voltage among the second plurality of discrete voltages is lower than a highest voltage among the first plurality of discrete voltages.

5. The radio frequency circuit according to claim 4, wherein an average of level differences between adjacent voltages of the second plurality of discrete voltages is smaller than an average of level differences between adjacent voltages of the first plurality of discrete voltages.

6. The radio frequency circuit according to claim 4, wherein the first switched-capacitor circuit is configured to generate the first plurality of discrete voltages by increasing and decreasing the regulated voltage.

7. The radio frequency circuit according to claim 6, wherein the second switched-capacitor circuit is configured to generate the second plurality of discrete voltages by decreasing the regulated voltage without increasing the regulated voltage.

8. The radio frequency circuit according to claim 4, wherein a number of the second plurality of discrete voltages is smaller than a number of the first plurality of discrete voltages.

9. The radio frequency circuit according to claim 2, wherein:
the second radio frequency signal is the millimeter-wave signal of the cellular network, and
a highest voltage among the second plurality of discrete voltages is higher than a highest voltage among the first plurality of discrete voltages.

10. The radio frequency circuit according to claim 9, wherein an average of level differences between adjacent voltages of the second plurality of discrete voltages is greater than an average of level differences between adjacent voltages of the first plurality of discrete voltages.

11. A tracker module comprising:
a module laminate;
at least one integrated circuit on the module laminate and including a first switched-capacitor circuit having a plurality of switches, a second switched-capacitor circuit, a first supply modulator, and a second supply modulator;
a first external connection terminal externally connected to a first power amplifier that is configured to amplify a first radio frequency signal; and
a second external connection terminal externally connected to a second power amplifier that is configured to amplify a second radio frequency signal,
wherein the first switched-capacitor circuit is configured to generate a first plurality of discrete voltages based on a regulated voltage,
wherein the second switched-capacitor circuit is configured to generate a second plurality of discrete voltages based on the regulated voltage,
wherein the first supply modulator is configured to selectively output at least one voltage of the first plurality of discrete voltages to the first external connection terminal based on the first radio frequency signal,
wherein the second supply modulator is configured to selectively output at least one voltage of the second plurality of discrete voltages to the second external connection terminal based on the second radio frequency signal, and
wherein the first radio frequency signal is a different signal than the second radio frequency signal.

12. The tracker module according to claim 11, wherein:
the first radio frequency signal is a Sub6 signal of a cellular network, and
the second radio frequency signal is a wireless local area network signal or a millimeter-wave signal of the cellular network.

13. The tracker module according to claim 12, wherein the second radio frequency signal is the wireless local area network signal.

14. The tracker module according to claim 13, wherein a highest voltage among the second plurality of discrete voltages is lower than a highest voltage among the first plurality of discrete voltages.

15. The tracker module according to claim 14, wherein an average of level differences between adjacent voltages of the second plurality of discrete voltages is smaller than an average of level differences between adjacent voltages of the first plurality of discrete voltages.

16. The tracker module according to claim 14, wherein the first switched-capacitor circuit is configured to generate the first plurality of discrete voltages by increasing and decreasing the regulated voltage.

17. The tracker module according to claim 16, wherein the second switched-capacitor circuit is configured to generate the second plurality of discrete voltages by decreasing the regulated voltage without increasing the regulated voltage.

18. The tracker module according to claim 14, wherein a number of the second plurality of discrete voltages is smaller than a number of the first plurality of discrete voltages.

19. An amplification method comprising:
converting an input voltage into a regulated voltage;
generating a first plurality of discrete voltages based on the regulated voltage;
selectively supplying at least one voltage of the first plurality of discrete voltages to a first power amplifier based on an envelope signal of a first radio frequency signal;
amplifying the first radio frequency signal with the first power amplifier;
generating a second plurality of discrete voltages based on the regulated voltage;
selectively supplying at least one voltage of the second plurality of discrete voltages to a second power amplifier based on an envelope signal of a second radio frequency signal; and
amplifying the second radio frequency signal with the second power amplifier,
wherein the first radio frequency signal is a different signal than the second radio frequency signal.

20. The amplification method according to claim 19, wherein:
the first radio frequency signal is a Sub6 signal of a cellular network, and
the second radio frequency signal is a wireless local area network signal or a millimeter-wave signal of the cellular network.
